(19) United States
(12) Patent Application Publication
(10) Pub. No.: US 2026/0026173 A1
(43) Pub. Date: Jan. 22, 2026

(54) Light-Emitting Substrate and Manufacturing Method Thereof, Backlight Module, and Display Apparatus

(71) Applicant: BOE TECHNOLOGY GROUP CO., LTD., Chaoyang District, Beijing (CN)

(72) Inventors: Haixu Li, Beijing (CN); Zhanfeng Cao, Beijing (CN); Yingwei Liu, Beijing (CN); Hebin Zhao, Beijing (CN); Yonglian Qi, Beijing (CN); Mengping Li, Beijing (CN)

(21) Appl. No.: 18/859,324

(22) PCT Filed: Sep. 15, 2023
(86) PCT No.: PCT/CN2023/119235

§ 371 Date: Oct. 23, 2024

(51) Int. Cl. H10H 29/851; H10H 29/856

(52) U.S. Cl. CPC H10H 29/8514; H10H 29/856

(57) ABSTRACT

A light-emitting substrate includes a substrate, light-emitting devices, a color conversion layer and a first reflective layer. The substrate has a first surface and a second surface that are opposite to each other; the second surface of the substrate is provided with a second recess therein. The light-emitting devices are disposed on the first surface of the substrate; a light-emitting device includes a light exit region. The color conversion layer is disposed on a side of the light-emitting device toward the second surface. The color conversion layer is located in the second recess, and an orthographic projection of the light exit region of the light-emitting device on the substrate is located within a range of the color conversion layer on the substrate. The first reflective layer is disposed on a side of the light-emitting device away from the substrate and covers at least the light-emitting device.

### CROSS-REFERENCE TO RELATED APPLICATION

This application is the United States national phase of International Patent Application No. PCT/CN2023/119235, filed Sep. 15, 2023, the disclosure of which is hereby incorporated by reference in its entirety.

### BACKGROUND OF THE INVENTION

### Field of the Invention

The present disclosure relates to the field of display technologies, and in particular, to a light-emitting substrate and a manufacturing method thereof, a backlight module, and a display apparatus.

### Description of Related Art

With the development of light-emitting diode technologies, a light-emitting substrate adopting submillimeter level (mini) light-emitting diodes (LED) or even micron level (micro) LEDs has been widely applied. Therefore, a product adopting such a light-emitting substrate, such as a liquid crystal display (LCD), not only has a picture contrast reaching a level of an organic light-emitting diode (OLED) display product, but also retains the technical advantages of the liquid crystal display, thereby improving the display effect of images and providing good visual experience for users.

### SUMMARY OF THE INVENTION

In an aspect, a light-emitting substrate is provided. The light-emitting substrate includes a substrate, light-emitting devices, a color conversion layer and a first reflective layer. The substrate has a first surface and a second surface that are opposite to each other; the second surface of the substrate is provided with a second recess therein. The light-emitting devices are disposed on the first surface of the substrate; a light-emitting device of the light-emitting devices includes a light exit region. The color conversion layer is disposed on a side of the light-emitting device toward the second surface. The color conversion layer is located in the second recess, and an orthographic projection of the light exit region of the light-emitting device on the substrate is located within an orthographic projection of the color conversion layer on the substrate. The first reflective layer is disposed on a side of the light-emitting device away from the substrate and covers at least the light-emitting device.

In some embodiments, the light-emitting substrate further includes a first light-homogenizing structure disposed in the second recess of the substrate. The first light-homogenizing structure is configured to scatter received light.

In some embodiments, the first light-homogenizing structure includes a plurality of first protrusions, and the plurality of first protrusions are disposed on a bottom wall of the second recess of the substrate.

In some embodiments, the first protrusions are substantially in a shape of at least one of a cone, a pyramid, and a spherical cap.

In some embodiments, the first light-homogenizing structure includes a scattering layer, and the scattering layer is disposed on a side of the color conversion layer proximate to or away from the substrate.

In some embodiments, the light-emitting substrate further includes a reflective structure, the reflective structure is disposed in the second recess of the substrate and located on a side of the color conversion layer away from the substrate. The reflective structure is configured to reflect received light.

In some embodiments, the reflective structure includes a plurality of reflective patterns, and the plurality of reflective patterns are arranged at intervals.

In some embodiments, orthographic projections of the reflective patterns on the substrate are substantially in a shape of at least one of a circle, an ellipse, and a polygon.

In some embodiments, the first surface of the substrate is provided with first recesses therein, and at least a portion of the light-emitting device is located in a first recess.

In some embodiments, the light-emitting substrate further includes a first transparent conductive layer, a first semiconductor layer, a first conductive layer, and a second conductive layer.

The first transparent conductive layer is disposed on the first surface of the substrate and located on a side of the light-emitting device proximate to the substrate. The first transparent conductive layer includes a first electrode, the first electrode is located in the first recess and extends outside the first recess. A surface of the light-emitting device proximate to the substrate is connected to a portion of the first electrode located in the first recess.

The first semiconductor layer is disposed on a side of the first transparent conductive layer away from the substrate. The first semiconductor layer includes a channel. The first conductive layer is disposed on a side of the first semiconductor layer away from the substrate. The first conductive layer includes a first gate line and a first transition line. The first gate line overlaps with the channel; the first transition line is connected to a portion of the first electrode located outside the first recess.

The second conductive layer is disposed on a side of the first conductive layer away from the substrate. The second conductive layer includes a source, a drain, a second electrode and a first connection line. A surface of the light-emitting device away from the substrate is connected to the second electrode, and one of the source and the drain is connected to the second electrode through the first connection line; the source and the drain are both connected to the channel.

In some embodiments, the light-emitting substrate further includes a second transparent conductive layer, a second semiconductor layer, a third conductive layer, and a fourth conductive layer.

The second transparent conductive layer is disposed on the first surface of the substrate and located on a side of the light-emitting device proximate to the substrate.

The second transparent conductive layer includes a first electrode and a second electrode, and the first electrode and the second electrode are both located in the first recess and extend outside the first recess. A surface of the light-emitting device proximate to the substrate is connected to portions of the first electrode and the second electrode that are located in the first recess.

The second semiconductor layer is disposed on a side of the second transparent conductive layer away from the substrate. The second semiconductor layer includes a channel. The third conductive layer is disposed on a side of the second semiconductor layer away from the substrate. The third conductive layer includes a second gate line and a second transition line. The second gate line overlaps with the channel. The second transition line is connected to a portion of the first electrode located outside the first recess.

The fourth conductive layer is disposed on a side of the third conductive layer away from the substrate. The fourth conducive layer includes a source, a drain and a third transition line. One of the source and the drain is connected to a portion of the second electrode located outside the first recess through the third transition line; the source and the drain are both connected to the channel.

In some embodiments, orthographic projections of at least two light-emitting devices of the light-emitting devices on the second surface of the substrate are located within an orthographic projection of a same first recess on the second surface of the substrate.

In some embodiments, the light-emitting devices are arranged in an array, and orthographic projections of light exit regions of at least two light-emitting devices in a same row or a same column are located within an orthographic projection of a same first recess on the second surface of the substrate.

In some embodiments, the light-emitting substrate includes light-emitting units. Each light-emitting unit includes multiple light-emitting devices that are connected in series and/or in parallel. Orthographic projections of light exit regions of light-emitting devices that belongs to a same light-emitting unit on the second surface of the substrate are located within an orthographic projection of a same first recess on the second surface of the substrate.

In some embodiments, orthographic projections of light exit regions of all the light-emitting devices on the second surface of the substrate are located within an orthographic projection of a same first recess on the second surface of the substrate.

In some embodiments, the substrate further includes a side surface connected to the first surface and the second surface, the light-emitting substrate further includes a light leakage preventing layer, and the light leakage prevention layer is disposed on the side surface of the substrate.

In some embodiments, the first surface of the substrate is provided with a first recess therein, a distance between a border of an orthographic projection of a bottom wall of the first recess on the second surface of the substrate and a border of an orthographic projection of the light exit region of the light-emitting device on the second surface of the substrate is a first distance, and a distance between the light-emitting device and the bottom wall of the first recess is a second distance. The first distance is greater than or equal to a product of the second distance and a tangent value of a light exit angle of the light exit region of the light-emitting device.

In some embodiments, a distance between a border of an orthographic projection of a bottom wall of the second recess on the second surface of the substrate and a border of an orthographic projection of the light exit region of the light-emitting device on the second surface of the substrate is a third distance, and a distance between the light-emitting device and the bottom wall of the second recess is a fourth distance. The third distance is greater than or equal to a product of the fourth distance and a tangent value of a light exit angle of the light exit region of the light-emitting device.

In some embodiments, the light-emitting substrate further includes a second reflective layer, the second reflective layer exposes at least a region where the light exit region of the light-emitting device is located.

In some embodiments, the light-emitting substrate further includes a first encapsulation layer, the first sealing layer is disposed on a side of the color conversion layer away from the substrate.

In another aspect, a light-emitting substrate is provided. The light-emitting substrate includes a substrate, a light-emitting device, a color conversion layer and a first reflective layer. The substrate has a first surface and a second surface that are opposite to each other. The first surface of the substrate is provided with a first recess therein, and a bottom wall of the first recess of the substrate is provided with a plurality of first protrusions thereon. The light-emitting device is disposed on the first surface of the substrate. The light-emitting device includes a light exit region. The color conversion layer is disposed on a side of the light-emitting device toward the second surface. An orthographic projection of the light exit region of the light-emitting device on the substrate is located within an orthographic projection of the color conversion layer on the substrate. The first reflective layer is disposed on a side of the light-emitting device away from the substrate and covers at least the light-emitting device.

In some embodiments, the color conversion layer is located in the first recess; and/or at least a portion of the light-emitting device is located in the first recess.

In another aspect, a light-emitting substrate is provided. The light-emitting substrate includes a substrate, a light-emitting device, a color conversion layer, a first reflective layer and a reflective structure. The substrate has a first surface and a second surface that are opposite to each other. The first surface of the substrate is provided with a first recess therein. The light-emitting device is disposed on the first surface of the substrate. The light-emitting device includes a light exit region. The color conversion layer is disposed on a side of the light-emitting device toward the second surface. An orthographic projection of the light exit region of the light-emitting device on the substrate is located within an orthographic projection of the color conversion layer on the substrate. The first reflective layer is disposed on a side of the light-emitting device away from the substrate and covers at least the light-emitting device. The reflective structure is disposed in the first recess of the substrate and configured to reflect received light.

In some embodiments, the color conversion layer is located in the first recess and located on a side of the reflective structure away from the substrate; and/or at least a portion of the light-emitting device is located in the first recess.

In another aspect, a backlight module is provided. The backlight module includes the light-emitting substrate in any one of the above embodiments, a diffusion sheet and a composite film. The light-emitting substrate has a light exit side and a non-light exit side that are opposite to each other. The diffusion sheet is disposed on the light exit side of the light-emitting substrate. The composite film is disposed on a side of the diffusion sheet away from the light-emitting substrate.

In another aspect, a display apparatus is provided. The display apparatus includes the backlight module in any one of the above embodiments and a display panel. The display panel is disposed on a side of the composite film in the backlight module away from the light-emitting substrate.

In another aspect, a manufacturing method of a light-emitting substrate is provided. The manufacturing method of the light-emitting substrate is used to manufacture the above light-emitting substrate, and the manufacturing method includes the following steps. Forming the second recess in the second surface of the substrate. Forming the color conversion layer in the second recess. Forming the light-emitting device on the first surface of the substrate. The first surface and the second surface being two opposite surfaces of the substrate. The light-emitting device including the light exit region, and the orthographic projection of the light exit region of the light-emitting device on the substrate being located within the orthographic projection of the color conversion layer on the substrate. Forming the first reflective layer on the side of the light-emitting device away from the substrate. The first reflective layer covering at least the light-emitting device.

In some embodiments, between forming the second recess in the second surface of the substrate and forming the color conversion layer in the second recess, and the manufacturing method further includes: etching a bottom wall of the second recess to form a plurality of first protrusions on the bottom wall of the second recess.

In some embodiments, before forming the light-emitting device on the first surface of the substrate, the manufacturing method further includes: forming a first recess in the first surface of the substrate. At least a portion of the light-emitting device being located in the first recess.

In some embodiments, the manufacturing method further includes: forming a reflective structure in the second recess. The reflective structure being disposed on a side of the color conversion layer away from the substrate.

In another aspect, a manufacturing method of a light-emitting substrate is provided. The manufacturing method of the light-emitting substrate is used to manufacture the above light-emitting substrate, and the manufacturing method includes the following steps. Forming the first recess on the first surface of the substrate. Etching the bottom wall of the first recess to form the plurality of first protrusions on the bottom wall of the first recess. Forming the color conversion layer. The color conversion layer being disposed on the second surface of the substrate or disposed in the first recess; the first surface and the second surface being two opposite surfaces of the substrate. Forming the light-emitting device on the first surface of the substrate. The light-emitting device including the light exit region, and the orthographic projection of the light exit region of the light-emitting device on the substrate being located within the orthographic projection of the color conversion layer on the substrate. Forming the first reflective layer on the side of the light-emitting device away from the substrate. The first reflective layer covering at least the light-emitting device.

In another aspect, a manufacturing method of a light-emitting substrate is provided. The manufacturing method of the light-emitting substrate is used to manufacture the above light-emitting substrate, and the manufacturing method includes the following steps. Forming the first recess on the first surface of the substrate. Forming the reflective structure in the first recess. Forming the color conversion layer. The color conversion layer being disposed on the second surface of the substrate or disposed in the first recess. The first surface and the second surface being two opposite surfaces of the substrate. The color conversion layer being located on the side of the reflective structure away from the substrate. Forming the light-emitting device on the first surface of the substrate. The light-emitting device including the light exit region, and the orthographic projection of the light exit region of the light-emitting device on the substrate being located within the orthographic projection of the color conversion layer on the substrate. Forming the first reflective layer on the side of the light-emitting device away from the substrate. The first reflective layer covering at least the light-emitting device.

### BRIEF DESCRIPTION OF THE DRAWINGS

In order to describe technical solutions in the present disclosure more clearly, the accompanying drawings to be used in some embodiments of the present disclosure will be briefly introduced below. Obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments;

FIG. 2 is a structural diagram of another display apparatus, in accordance with some embodiments;

FIG. 3 is a sectional view of a display apparatus, in accordance with some embodiments;

FIG. 4 is a top view of a light-emitting substrate, in accordance with some embodiments;

FIG. 5 is a structural diagram of a light-emitting substrate, in accordance with some embodiments;

FIG. 6 is a structural diagram of another light-emitting substrate, in accordance with some embodiments;

FIG. 7 is a structural diagram of yet another light-emitting substrate, in accordance with some embodiments;

FIG. 8 is a structural diagram of yet another light-emitting substrate, in accordance with some embodiments;

FIG. 9 is a structural diagram of yet another light-emitting substrate, in accordance with some embodiments;

FIG. 10 is a structural diagram of yet another light-emitting substrate, in accordance with some embodiments;

FIG. 11 is a structural diagram of yet another light-emitting substrate, in accordance with some embodiments;

FIG. 12 is a structural diagram of yet another light-emitting substrate, in accordance with some embodiments;

FIG. 13 is a top view of a light-emitting substrate, in accordance with some embodiments;

FIG. 14 is a top view of another light-emitting substrate, in accordance with some embodiments;

FIG. 15 is a top view of yet another light-emitting substrate, in accordance with some embodiments;

FIG. 16 is a top view of yet another light-emitting substrate, in accordance with some embodiments;

FIGS. 17 to 22 are each a flow diagram of a manufacturing method of a light-emitting substrate, in accordance with some embodiments;

FIGS. 23 to 26 are diagrams each showing processes of a manufacturing method of a light-emitting substrate, in accordance with some embodiments;

FIG. 27 is a structural diagram of yet another light-emitting substrate, in accordance with some embodiments;

FIG. 28 is a flow diagram of a manufacturing method of the light-emitting substrate shown in FIG. 27;

FIG. 29 is a diagram showing processes of a manufacturing method of the light-emitting substrate shown in FIG. 27;

FIG. 30 is a structural diagram of yet another light-emitting substrate, in accordance with some embodiments;

FIG. 31 is a flow diagram of a manufacturing method of the light-emitting substrate shown in FIG. 30; and

FIG. 32 is a diagram showing processes of a manufacturing method of the light-emitting substrate shown in FIG. 30.

### DESCRIPTION OF THE INVENTION

The technical solutions in some embodiments of the present disclosure will be described clearly and completely below in conjunction with the accompanying drawings. Obviously, the embodiments to be described are merely some but not all embodiments of the present disclosure. All other embodiments obtained by a person of ordinary skill in the art based on the embodiments provided in the present disclosure should belong to the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment”, “some embodiments”, “exemplary embodiments”, “example”, “specific example”, or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

In the following, the terms “first” and “second” are used for descriptive purposes only, and are not to be construed as indicating or implying the relative importance or implicitly indicating the number of indicated technical features. Thus, a feature defined with “first” or “second” may explicitly or implicitly include one or more of the features. In the description of the embodiments of the present disclosure, the term “a/the plurality of” means two or more unless otherwise specified.

In the description of some embodiments, the terms “coupled” and “connected” and derivatives thereof may be used. The term “connected” should be understood in a broad sense. For example, the term “connected” may represent a fixed connection, or a detachable connection, or a one-piece connection; alternatively, the term “connected” may represent a direct connection, or an indirect connection through an intermediate medium. For example, the term “coupled” indicates that two or more components are in direct physical or electrical contact. The term “coupled” or “communicatively coupled” may also indicate that two or more components are not in direct contact with each other, but still cooperate or interact with each other. The embodiments disclosed herein are not necessarily limited to the context herein.

The phrase “at least one of A, B and C” has the same meaning as the phrase “at least one of A, B or C”, both including following combinations of A, B and C: only A, only B, only C, a combination of A and B, a combination of A and C, a combination of B and C, and a combination of A, B and C.

The phrase “A and/or B” includes following three combinations: only A, only B, and a combination of A and B.

The phrase “applicable to” or “configured to” used herein means an open and inclusive expression, which does not exclude devices that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or values exceeding those stated.

The term such as “about”, “substantially” or “approximately” as used herein includes a stated value and an average value within an acceptable range of deviation of a particular value, and the acceptable range of deviation is determined, for example, by a person of ordinary skill in the art, considering measurement in question and errors (i.e., limitations of a measurement system) associated with measurement of a particular quantity.

The term such as “parallel”, “perpendicular” or “equal” as used herein includes a stated condition and a condition similar to the stated condition within an acceptable range of deviation, and the acceptable range of deviation is determined, for example, by a person of ordinary skill in the art, considering measurement in question and errors (i.e., limitations of a measurement system) associated with measurement of a particular quantity. For example, the term “equal” includes absolute equality and approximate equality, where an acceptable range of deviation of the approximate equality may be, for example, a difference between two equals of less than or equal to 5% of either of the two equals.

It will be understood that, in a case where a layer or element is referred to as being on another layer or substrate, it may be that the layer or element is directly on the another layer or substrate, or there may be an intermediate layer between the layer or element and the another layer or substrate.

Exemplary embodiments are described herein with reference to sectional views and/or plan views as idealized exemplary drawings. In the accompanying drawings, thickness of layers and sizes of regions are enlarged for clarity. Thus, variations in shapes with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a curved feature. Therefore, the regions shown in the accompanying drawings are schematic in nature, and their shapes are not intended to show actual shapes of the regions in an apparatus, and are not intended to limit the scope of the exemplary embodiments.

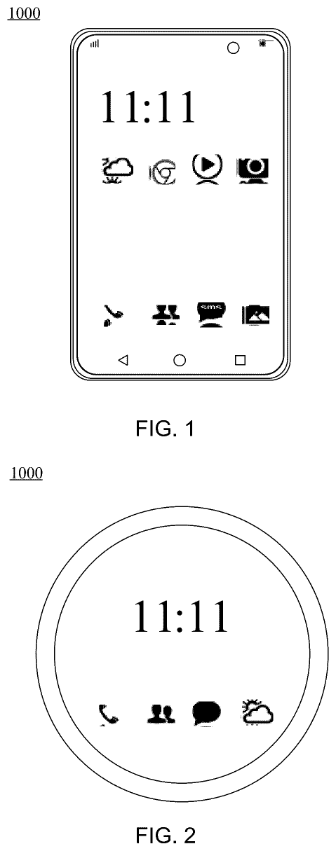

As shown in FIG. 1, some embodiments of the present disclosure provide a display apparatus 1000, and the display apparatus 1000 may be any apparatus that displays images whether in motion (e.g., videos) or stationary (e.g., static images), and whether textual or graphical.

For example, referring to FIGS. 1 and 2, the display apparatus 1000 may be any product or component having a display function, such as a television, a notebook computer, a tablet computer, a mobile phone, a personal digital assistant (PDA), a navigator, a wearable device, or a virtual reality (VR) device.

For example, as shown in FIG. 1, the display apparatus 1000 may be a portable display product; for example, the display apparatus 1000 may be the mobile phone shown in FIG. 1. For another example, referring to FIG. 2, the display apparatus 1000 may be a wearable device; for example, the display apparatus 1000 may be the watch shown in FIG. 2.

It should be noted that, depending on different application scenarios, the shape of the display surface of the display apparatus 1000 is not unique, and the shape of the display surface of the display apparatus 1000 may be any one of circle, ellipse or polygon, which is not specifically limited in the embodiments of the present disclosure.

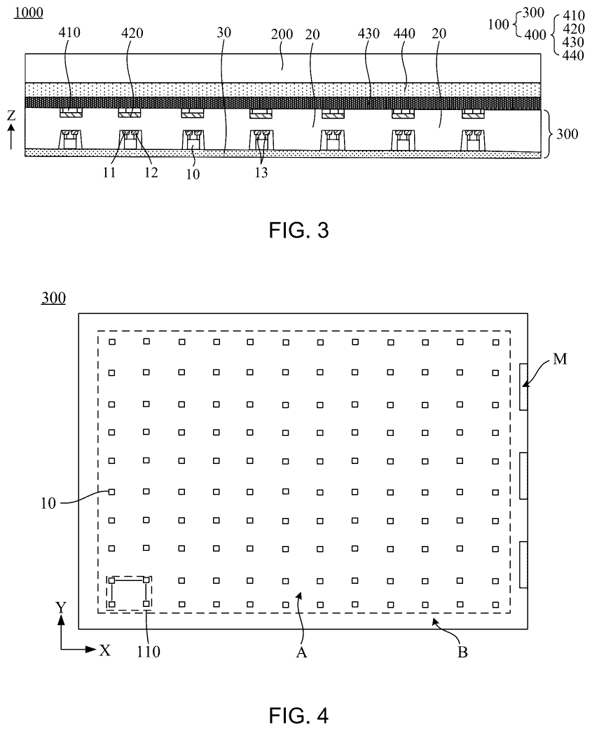

In some embodiments, referring to FIG. 3, the display apparatus 1000 may be a liquid crystal display (LCD) apparatus.

For example, referring to FIG. 3, the display apparatus 1000 includes a backlight module 100 and a display panel 200.

Referring to FIG. 3, the backlight module 100 includes a light-emitting substrate 300, and the light-emitting substrate 300 has a light exit side and a non-light exit side that are opposite to each other. The light exit side refers to a side (an upper side of the light-emitting substrate 300 in FIG. 3) of the light-emitting substrate 300 where light exits, and the non-light exit side refers to the other side (a lower side of the light-emitting substrate 300 in FIG. 3) opposite to the light exit side. The display panel 200 is disposed on the light exit side of the light-emitting substrate 300.

In some examples, referring to FIG. 4, the light-emitting substrate 300 has a light-emitting region A and a peripheral region B, and the peripheral region B is disposed on at least one side of the light-emitting region A. FIG. 4 is illustrated by taking an example in which the peripheral region B surrounds the light-emitting region A. The light-emitting region A is configured to be provided with light-emitting devices 10 therein, and the peripheral region B is configured to be provided with circuit wirings and connect a driving circuit board therein. For example, the peripheral region B may include a bonding region M, and the bonding region M is configured to connect a driving circuit board therein.

As shown in FIG. 4, the light-emitting substrate 300 includes a plurality of light-emitting devices 10, and the plurality of light-emitting devices 10 are disposed in the light-emitting region A. The light-emitting devices 10 may include micro LEDs and/or mini LEDs. It will be noted that, a size (e.g., a length) of a micro LED may be less than 50 microns, for example, in a range of 10 microns to 50 microns, inclusive. A size (e.g., a length) of a mini LED is in a range of 50 microns to 150 microns, inclusive, for example, in a range of 80 microns to 120 microns, inclusive.

In some examples, referring to FIG. 4, the plurality of light-emitting devices 10 are arranged in an array. For example, the plurality of light-emitting devices 10 are arranged in multiple rows and multiple columns, each row includes at least two light-emitting devices 10 arranged in a first direction X, and each column includes at least two light-emitting devices 10 arranged in a second direction Y. It will be noted that, the first direction X intersects with the second direction; for example, the first direction X is perpendicular to the second direction Y.

In addition, referring to FIG. 3, the backlight module 100 may further include a plurality of optical films 400. The light emitted by the light-emitting devices 10 passes through the optical films 400 and then propagates toward the display panel 200. That is, the display panel 200 is disposed on a side of the optical films 400 away from the light-emitting substrate 300. It will be noted that the optical films 400 modulate the wavelength and/or propagation direction of light emitted by the light-emitting devices 10.

As shown in FIG. 3, the light-emitting devices 10 may directly emit white light, and the propagation direction of the white light is modulated after passing through the plurality of optical films 400 and then propagates toward the display panel 200. Alternatively, the light-emitting devices 10 may emit light of other colors (e.g., blue light), which is modulated in wavelength and/or propagation direction after passing through the plurality of optical films 400 and then propagates to the display panel 200.

For example, referring to FIG. 3, the plurality of optical films 400 include a scattering layer 410, a color conversion layer 420, a diffusion sheet 430 and a composite film 440. The scattering layer 410, the color conversion layer 420, the diffusion sheet 430 and the composite film 440 may be, for example, sequentially arranged in a direction away from the display panel 200. That is, the diffusion sheet 430 may be disposed on the light exit side of the light-emitting substrate 300, the composite film 440 is disposed on a side of the diffusion sheet 430 away from the light-emitting substrate 300, the scattering layer 410 and the color conversion layer 420 are disposed on a side of the diffusion sheet 430 proximate to the light-emitting substrate 300, and the display panel 200 is disposed on a side of the composite film 440 away from the light-emitting substrate 300.

The scattering layer 410 can blur the light emitted by the light-emitting devices 10 and provide support for the color conversion layer 420, the diffusion sheet 430 and the composite film 440. The color conversion layer 420 may, due to the excitation of light of a certain color emitted by the light-emitting devices 10, convert the light into white light, so as to improve a utilization rate of light energy of the light-emitting devices 10. The diffusion sheet 430 can homogenize the light passing through the diffusion sheet 430. The composite film 440 can improve the light extraction efficiency of the light-emitting substrate 300, thereby increasing the display brightness of the display apparatus 1000.

It will be noted that, the scattering layer 410 includes scattering particles, and the scattering particles include titanium dioxide and/or silicon dioxide. The color conversion layer 420 includes a quantum dot material or a fluorescent material. The composite film 440 may include a brightness enhancement film (BEF) and a dual brightness enhancement film (DBEF), which may increase the light flux within a certain angle range by using the principles of total reflection, refraction and polarization, so as to improve the brightness of the display apparatus 1000.

For example, as shown in FIG. 3, the light-emitting devices 10 emit blue light. The color conversion layer 420 may include a red quantum dot material, a green quantum dot material and a transparent material. When the blue light emitted by the light-emitting devices 10 passes through the red quantum dot material, the blue light is converted into red light; when the blue light passes through the green quantum dot material, the blue light is converted into green light; the blue light may directly pass through the transparent material; then, the blue light, red light and green light are mixed in a certain proportion to present white light. Finally, the scattering layer 410 and the diffusion sheet 430 can modulate the incident light of different propagation directions and the light is emitted uniformly, so as to alleviate light shadows produced by the light-emitting substrate 300 and improve the display quality of the display apparatus 1000.

In some related art, the scattering layer, the color conversion layer, the diffusion sheet and the composite film are all disposed between the light-emitting substrate and the display panel, which results in a relatively large thickness of the entire display apparatus and is not conducive to the design of thinness and lightness of the display apparatus.

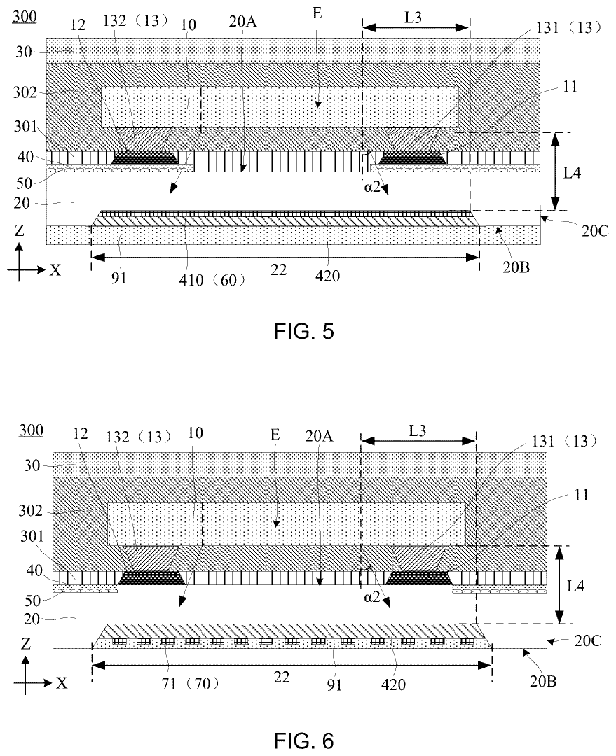

Based on this, referring to FIGS. 5 to 12, some embodiments of the present disclosure provide a light-emitting substrate 300, which includes light-emitting devices 10, a substrate 20, a first reflective layer 30 and a color conversion layer 420.

As shown in FIGS. 5 to 12, the substrate 20 has a first surface 20A, a second surface 20B that are opposite to each other, and a side surface 20C connected to the first surface 20A and the second surface 20B. The second surface 20B of the substrate 20 is provided with a second recess 22.

It will be noted that a material of the substrate 20 may include a rigid material. For example, the material of the substrate 20 includes any one of glass, quartz, or polymethyl methacrylate (PMMA).

As shown in FIGS. 5 to 12, the light-emitting devices 10 are disposed on the first surface 20A of the substrate 20. A light-emitting device 10 includes a light exit region E, and an orthographic projection of the light exit region E on the substrate 20 is located within an orthographic projection of the color conversion layer 420 on the substrate 20. It will be noted that, the light exit region E refers to a region where the light that the light-emitting device 10 actively emits can exit when the light-emitting device 10 is in operation. Generally, a light-emitting device 10 has pin structures 13 connected to an external circuit structure (e.g., a first pad 11 and a second pad 12). The pin structures 13 are generally made of metal or an alloy material that have a relative good conductivity. The light that the light-emitting device 10 actively emits can be emitted from all other regions except for regions where the pin structures 13 are located. FIGS. 5 to 8 are illustrated by taking an example in which the light exit region E is located between the pin structures 13, and in practice, the light exit region E is not necessarily a regular region, and the embodiments of the present disclosure do not specifically limit thereto.

As shown in FIGS. 5 to 12, the color conversion layer 420 is disposed on a side of the light-emitting devices 10 facing the second surface 20B. Furthermore, the color conversion layer 420 is located in the second recess 22.

In this case, the color conversion layer 420 located in the second recess 22 and the substrate 20 together occupy part of a dimension of the display apparatus 1000 in a third direction Z (a thickness direction of the display apparatus 1000); that is, the color conversion layer 420 located in the second recess 22 does not need to occupy additional dimension of the display apparatus 1000 in the third direction Z. Based on this, in comparison with the related art, the thickness of the display apparatus 1000 provided by the embodiments of the present disclosure is reduced, so that the display apparatus 1000 is thinner and lighter.

It will be noted that, the third direction Z is perpendicular to the first surface 20A of the substrate 20; that is, the third direction Z is perpendicular to the first direction X and perpendicular to the second direction Y.

As shown in FIGS. 5 to 12, the first reflective layer 30 is disposed on a side of the light-emitting devices 10 away from the substrate 20, and covers at least the light-emitting devices 10. In this way, the light emitted from the light-emitting devices 10 and directed toward the first reflective layer 30 is reflected and then is emitted from the second surface 20B of the substrate 20, thereby increasing the light extraction efficiency.

A reflectivity of the first reflective layer 30 is greater than or equal to 85%. For example, a material of the first reflective layer 30 may include metal, such as at least one of aluminum, silver, copper, and platinum. For example, the material of the first reflective layer 30 may include white ink and/or silicone-based white adhesive.

It can be known from the above that, the color conversion layer 420 and the light-emitting devices 10 are respectively disposed on opposite sides of the substrate 20, and the light-emitting devices 10 is covered with the first reflective layer 30 on a side away from the substrate 20. In this way, after the light emitted by the light-emitting devices 10 excites the color conversion layer 420, for the light emitted by the color conversion layer 420 in every direction, a part of the light is directed toward the outside of the substrate 20, while another part of the light enters the substrate 20 and is emitted uniformly from the second surface 20B of the substrate 20 after being reflected multiple times inside the substrate 20, so that the brightness uniformity of the light-emitting substrate 300 is improved. In addition, according to actual conditions, the light-emitting substrate 300 may not be provided with the scattering layer 410, so as to further reduce the thickness of the display apparatus 100 and make the display apparatus 1000 thin and light.

It will be understood that, the orthographic projection of the light exit region E on the substrate 20 is located within the orthographic projection of the color conversion layer 420 on the substrate 20, and the color conversion layer 420 is located in the second recess 22. That is, the orthographic projection of the light exit region E on the substrate 20 is located in the second recess 22. It will be noted that an orthographic projection on the substrate 20 refers to an orthographic projection on a plane where the first surface 20A of the substrate 20 is located.

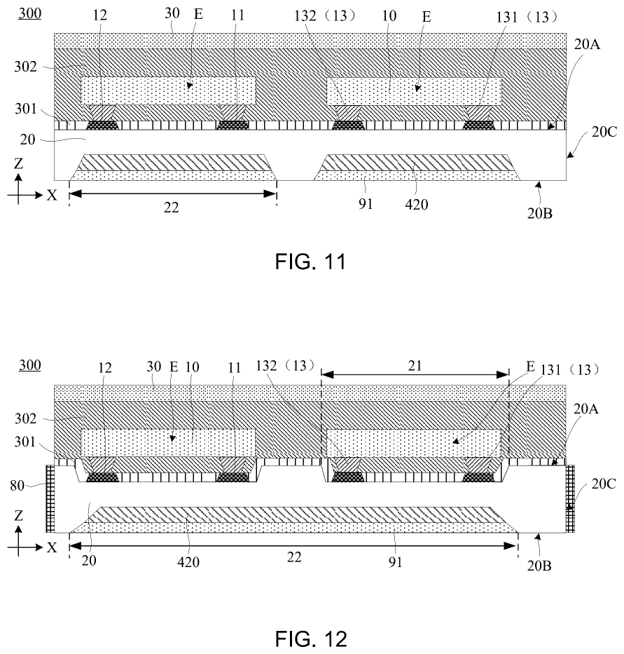

In some embodiments, referring to FIG. 11, an orthographic projection of a light exit region E of a light-emitting device 10 on the substrate 20 may be located within an orthographic projection of a second recess 22 on the substrate 20. With such an arrangement, an area of the substrate 20 that is occupied by the second recess 22 is relatively small, so that the substrate 20 may maintain a relatively high strength.

In some other embodiments, referring to FIG. 12, orthographic projections of light exit regions E of at least two light-emitting devices 10 on the substrate 20 may be located within an orthographic projection of a same second recess 22 on the substrate 20. For example, orthographic projections of light exit regions E of all the light-emitting devices 10 on the substrate 20 may be located in a same second recess 22, so as to reduce the number of the second recesses 22 and reduce process difficulty.

Some embodiments of the present disclosure will be exemplarily illustrated below by taking an example in which an orthographic projection of a light exit region E of a light-emitting device 10 on the substrate 20 is located within an orthographic projection of a second recess 22 on the substrate 20, but the embodiments of the present disclosure are not limited thereto.

Referring to FIGS. 5 and 6, a distance between a border of an orthographic projection of a bottom wall of the second recess 22 on the second surface 20B of the substrate 20 and a border of an orthographic projection of the light exit region E of the light-emitting device 10 on the second surface 20B of the substrate 20 is a third distance L3, and a distance between the light-emitting device 10 and the bottom wall of the second recess 22 is a fourth distance L4.

The third distance L3 is greater than or equal to a product of the fourth distance L4 and a tangent value of a light exit angle α2 of the light exit region E of the light-emitting device 10, so that all the light emitted by the light-emitting device 10 may be directed toward the bottom wall of the second recess 22, and thus may be emitted after being converted by the color conversion layer 420.

It will be noted that, herein, a luminous intensity of the outmost light of the light emitted by the light-emitting device 10 is half of a luminous intensity corresponding to a normal direction of the light-emitting device 10, and the “light exit angle” is a maximum angle between edge light and a normal of a light exit surface.

In some embodiments, as shown in FIGS. 11 and 12, due to the presence of the first reflective layer 30, a part of light that enters the substrate 20 from the color conversion layer 420 will be directed toward the first reflective layer 30, and is emitted from the second surface 20B of the substrate 20 after being reflected by the first reflective layer 30, thereby improving the brightness uniformity of the light-emitting substrate 300.

In this case, referring to FIG. 5, the first reflective layer 30 is a continuous whole layer structure and covers at least the entire light-emitting region A. For example, a border of the first reflective layer 30 substantially coincides with a border of the light-emitting region A.

In some embodiments, as shown in FIGS. 5 to 10, the light-emitting substrate 300 further includes a second reflective layer 40, the second reflective layer 40 is disposed on the first surface 20A of the substrate 20, and the second reflective layer 40 exposes at least a region where the light exit region E of the light-emitting device 10 is located. For example, as shown in FIG. 6, the second reflective layer 40 covers a region between light-emitting devices 10 and exposes a region where the light-emitting devices 10 are located.

In this case, due to the presence of the second reflective layer 40, a part of light entering the substrate 20 from the color conversion layer 420 will be directed toward the second reflective layer 40, and is emitted from the second surface 20B of the substrate 20 after being reflected by the second reflective layer 40, thereby improving the brightness uniformity of the light-emitting substrate 300.

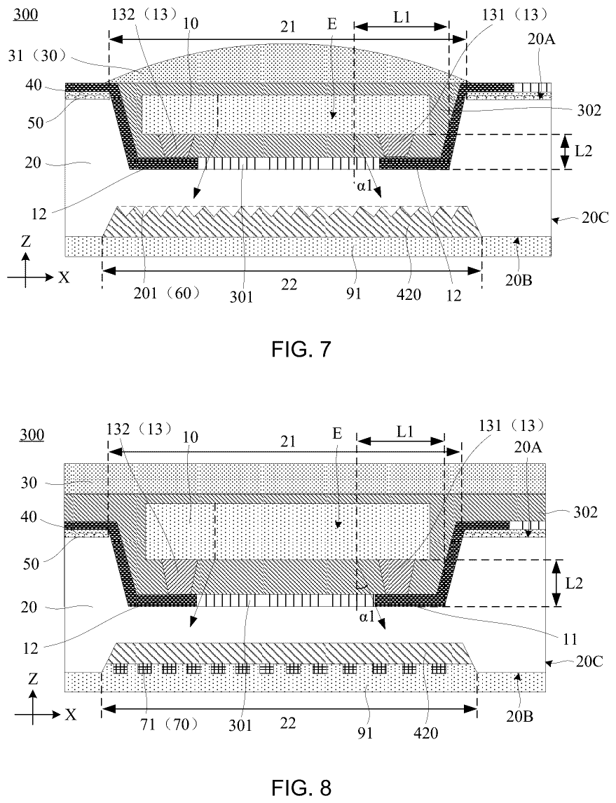

In this case, referring to FIGS. 5 and 7, the first reflective layer 30 may be a continuous whole layer structure, or may include a plurality of reflective portions 31 arranged at intervals. For example, as shown in FIG. 5, the first reflective layer 30 may be a continuous whole layer structure and cover the entire light-emitting region A. For example, as shown in FIG. 7, the first reflective layer 30 includes a plurality of reflective portions 31 arranged at intervals, and an orthographic projection of a light-emitting device 10 on the substrate 20 is located within an orthographic projection of a reflective portion 31 on the substrate 20.

A reflectivity of the second reflective layer 40 is greater than or equal to 85%. For example, a material of the second reflective layer 40 includes metal, such as at least one of aluminum, silver, copper, and platinum. For example, the material of the second reflective layer 40 includes white ink and/or silicone-based white adhesive.

Based on this, as shown in FIGS. 5 to 10, the light-emitting substrate 300 may further include a plurality of second light-homogenizing structures 50, the plurality of second light-homogenizing structures 50 are arranged between the second reflective layer 40 and the substrate 20, and the second light-homogenizing structures 50 are used to disperse the received light to scatter the light in every direction. In this case, for the light entering the substrate 20 from the color conversion layer 420, a part of light that is totally reflected by the second surface 20B of the substrate 20 will be reflected to the second light-homogenizing structures 50 and scattered by the second light-homogenizing structure 50 to change the propagation direction of the light, and the light is reflected by the second reflective layer 40, so that the light may be emitted from the second surface 20B of the substrate 20, and thus the brightness uniformity of the light-emitting substrate 300 is improved.

For example, the second light-homogenizing structures 50 may include a plurality of second protrusions, and the second protrusions are substantially in a shape of at least one of a cone, a pyramid, and a spherical cap. A material of the second light-homogenizing structures 50 includes a transparent resin.

Herein, “substantially in a shape of a cone or pyramid” refers to in a shape of a cone or a pyramid as a whole, but is not limited to a standard cone or pyramid. That is, the “cone and pyramid” here include not only shapes of a basic cone and pyramid but also shapes similar to cones and pyramids. For example, apex corners of cones and pyramids are curved surfaces.

Herein, “substantially in a shape of a spherical cap” refers to in a shape of a spherical cap as a whole, but is not limited to a standard spherical cap. That is, the “spherical cap” here includes not only a shape of a standard spherical cap but also shapes similar to a spherical cap. For example, an upper half of a spherical cap is a standard spherical cap, and a lower half is a cylinder.

In some embodiments, referring to FIGS. 5 and 7, the light-emitting substrate 300 further includes a first light-homogenizing structure 60. The first light-homogenizing structure 60 is disposed in the second recess 22 of the substrate 20 and is configured to scatter the received light.

In this case, the light emitted by the light-emitting device 10 towards the region where the second recess 22 is located may be dispersed by the first light-homogenizing structure 60 and emitted from other regions. Thus, the light output of the region where the second recess 22 is located is reduced, and the light output of the other regions between second recesses 22 is increased, so that the brightness uniformity of the light-emitting substrate 300 is improved.

Moreover, the first light-homogenizing structure 60 does not need to occupy additional dimension of the display apparatus 1000 in the third direction Z, which is beneficial for the lightness and thinness of the display apparatus 1000. That is, the brightness uniformity of the light-emitting substrate 300 may be improved without increasing the thickness of the display apparatus 1000.

In some examples, as shown in FIG. 7, a bottom wall of the second recess 22 of the substrate 20 is provided with a plurality of first protrusions 201 thereon, and the plurality of first protrusions 201 form a first light-homogenizing structure 60. The first protrusions 201 are substantially in a shape of at least one of a cone, a pyramid and a spherical cap. In this case, the first protrusions 201 disperse the incident light to scatter the light in every direction, thereby improving the brightness uniformity of the light-emitting substrate 300.

In addition, the first light-homogenizing structure 60 is disposed inside the substrate 20, so that there is no need to individually provide other film layers that play a light-homogenizing role in the second recess 22, which not only saves materials but also reduces a depth of the second recess 22. As a result, the thickness of the substrate 20 may be reduced, so that the thickness of the display apparatus 1000 is reduced, and the display apparatus 1000 is thinner and lighter.

In some other examples, as shown in FIG. 5, the first light-homogenizing structure 60 includes a scattering layer 410, and the scattering layer 410 is disposed on a side of the color conversion layer 420 proximate to or away from the substrate 20. The scattering layer 410 may include scattering particles, and the scattering particles may include titanium dioxide and/or silicon dioxide, for example. In this case, the scattering layer 410 may be directly formed in the second recess 22 by an inkjet printing process, and the fabricating process is simple; meanwhile, the thickness of the scattering layer 410 is relatively small, the depth of the second recess 22 is relatively small, and the thickness of the substrate 20 may be reduced, so as to further reduce the thickness of the display apparatus 1000, making the display apparatus 1000 thinner and lighter.

In some embodiments, referring to FIGS. 6 and 8, the light-emitting substrate 300 further includes a reflective structure 70. The reflective structure 70 is disposed in the second recess 22 of the substrate 20 and is configured to reflect the received light.

It will be noted that, the reflective structure 70 is located on a side of the color conversion layer 420 away from the substrate 20, so as to prevent the light emitted by the light-emitting device 10 from being directly emitted without being converted by the color conversion layer 420, thereby reducing the risk of color deviation.

In this case, for the light entering a region where the second recess 22 is located from the light-emitting device 10, a part of light may be reflected by the reflective structure 70 into the substrate 20 and emitted from other regions. Thus, the light output of the region where the second recess 22 is located is reduced, and the light output of other regions between second recesses 22 is increased, so that the brightness uniformity of the light-emitting substrate 300 is improved.

Moreover, the reflective structure 70 does not need to occupy additional dimension of the display apparatus 1000 in the third direction Z, which is beneficial for the thinness and lightness of the display apparatus 1000. That is, the brightness uniformity of the light-emitting substrate 300 may be improved without increasing the thickness of the display apparatus 1000.

For example, as shown in FIG. 8, the reflective structure 70 includes a plurality of reflective patterns 71, and the plurality of reflective patterns 71 may be arranged at intervals, for example. Orthographic projections of the reflective patterns 71 on the substrate are substantially in a shape of at least one of a circle, an ellipse, and a polygon.

Herein, “substantially in a shape of a circle or an ellipse” refers to in the shape of a circle or ellipse as a whole, but is not limited to a standard circle or ellipse. That is, the “circle or ellipse” here includes not only a shape of a basic circle or ellipse but also shapes similar to a circle or ellipse. For example, part of the border of a circle or ellipse is a straight line.

Herein, “substantially in a shape of a polygon” refers to in the shape of a polygon as a whole, but is not limited to a standard polygon. That is, the “polygon” here includes not only a shape of a basic circle or ellipse but also shapes similar to a polygon. For example, corners of a polygon are curved; that is, the corners of the polygon are smooth and in a shape of a rounded corner.

In addition, a material of the reflective patterns 71 includes metal, such as at least one of aluminum, silver, copper, and platinum. The reflective patterns 71 may be formed by using an evaporation process. In this case, due to the shadow effect of the evaporation, a slope exists at the edge of the reflective pattern 71. That is, the edge surface of the reflective pattern 71 is a slope.

In some embodiments, as shown in FIG. 12, the light-emitting substrate 300 further includes a light leakage preventing layer 80, and the light leakage preventing layer 80 is disposed on a side surface 20C of the substrate 20 to avoid the defects such as ghosting in the display apparatus 1000 due to the light leakage from the side surface 20C of the substrate 20.

In some embodiments, referring to FIGS. 5 to 12, the light-emitting substrate 300 further includes a first encapsulation layer 91, and the first encapsulation layer 91 is disposed on a side of the color conversion layer 420 away from the substrate 20 to protect the color conversion layer, so that the risk of failure of the color conversion layer 420 due to water and oxygen corrosion is reduced.

It will be noted that, referring to FIGS. 11 and 12, the first encapsulation layer 91 may be located in the second recess 22, which is conducive to the lightness and thinness of the display apparatus 1000. Referring to FIG. 8, the first encapsulation layer 91 may also be a continuous whole layer structure covering the entire light-emitting region A, a portion of which is located in the second recess 22, and another portion of which is located outside the second recess 22.

In some embodiments, referring to FIGS. 5 and 6, the first surface 20A of the substrate 20 is a flat surface, and the light-emitting devices 10 are directly disposed on the first surface 20A of the substrate 20.

In some other embodiments, referring to FIGS. 7 to 10, the first surface 20A of the substrate 20 is provided with a first recess 21 therein, and at least a portion of a light-emitting device 10 is located in the first recess 21. For example, as shown in FIG. 7, the entire light-emitting device 10 is located in the first recess 21. For another example, as shown in FIG. 8, in the third direction Z of the display apparatus 1000, a thickness of a light-emitting device 10 is greater than a depth of the first recess 21, a portion of the light-emitting device 10 is located in the first recess 21, and another portion of the light-emitting device 10 exceeds the opening of the first recess 21 and is exposed outside the first recess 21.

In this case, the portion of the light-emitting device 10 located in the first recess 21 and the substrate 20 together occupy part of the dimension of the display apparatus 1000 in the third direction Z, i.e., the portion of the light-emitting device 10 located in the first recess 21 does not need to additionally occupy the dimension of the display apparatus 1000 in the third direction Z, so that the thickness of the display apparatus 1000 may be further reduced, making the display apparatus 1000 thinner and lighter.

Some embodiments of the present disclosure will be exemplarily illustrated below by taking an example in which the first surface 20A of the substrate 20 is provided therein with a first recess 21 and at least a portion of a light-emitting device 10 is located in the first recess 21, but the embodiments of the present disclosure are not limited thereto.

Referring to FIGS. 7 and 8, a distance between a border of an orthographic projection of a bottom wall of the first recess 21 on the second surface 20B of the substrate 20 and a border of an orthographic projection of a light exit region E of the light-emitting device 10 on the second surface 20B of the substrate 20 is a first distance L1, and a distance between the light-emitting device 10 and the bottom wall of the first recess 21 is a second distance L2.

The first distance L1 is greater than or equal to a product of the second distance L2 and a tangent value of the light exit angle α1 of the light exit region E of the light-emitting device 10, so that all the light emitted by the light-emitting device 10 may be directed toward the bottom wall of the first recess 21 and toward the color conversion layer 420 in the second recess 22.

It will be noted that, herein, a luminous intensity of the outmost light of the light emitted by the light-emitting device 10 is half of a luminous intensity corresponding to a normal direction of the light-emitting device 10, and the “light exit angle” is a maximum angle between the outmost light and a normal of a light exit surface.

In some embodiments, referring to FIGS. 5 to 8, the light-emitting device 10 is fixed onto the first surface 20A of the substrate 20 by using a die bonding process.

For example, as shown in FIGS. 5 to 8, the light-emitting substrate 300 further includes a first wiring layer 301 and a first insulating layer 302. The first wiring layer 301 is disposed on the first surface 20A of the substrate 20, and the first wiring layer 301 includes a first pad 11, a second pad 12 and a driving transistor (not shown in FIGS. 5 to 8). A first pin 131 of the light-emitting device 10 is soldered to the first pad 11, and a second pin 132 of the light-emitting device 10 is soldered to the second pad 12. The first insulating layer 302 covers the light-emitting device 10 and fills the space between the light-emitting device 10 and the first wiring layer 301. Thus, it is possible to avoid the decrease of the light extraction efficiency of the light-emitting device 10 caused by a case that, during the process of fabricating the first reflective layer 30, a reflective material is formed between the light-emitting device 10 and the first wiring layer 301 or formed on a side surface of the light-emitting device 10.

It will be noted that, the first wiring layer 301 may include multiple conductive layers and multiple insulating layers for isolating adjacent conductive layers or protecting the conductive layers, which is not specifically limited in the embodiments of the present disclosure. A material of the first insulating layer 302 includes a transparent resin.

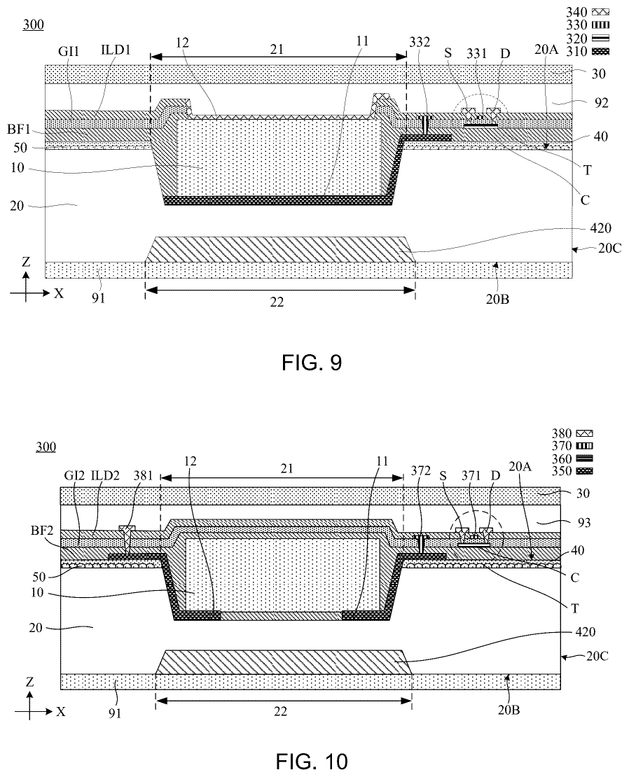

In some other embodiments, referring to FIGS. 9 and 10, the light-emitting device 10 and the driving transistor T may also be directly fabricated on the substrate 20 to avoid yield loss caused by the die bonding process.

For example, referring to FIG. 9, the light-emitting substrate 300 includes a first transparent conductive layer 310, a first semiconductor layer 320, a first conductive layer 330, and a second conductive layer 340.

As shown in FIG. 9, the first transparent conductive layer 310 is disposed on the first surface 20A of the substrate 20 and located on a side of the light-emitting device 10 proximate to the substrate 20. The first transparent conductive layer 310 includes a first electrode 11. The first electrode 11 is located in the first recess 21 and extends outside the first recess 21 for convenience of being connected to a voltage signal line.

It will be noted that, a material of the first transparent conductive layer 310 includes indium zinc oxide and/or indium tin oxide, so as to reduce the shielding for the light emitted by the light-emitting device 10 by the first electrode 11 and improve the light extraction efficiency of the light-emitting substrate 300.

As shown in FIG. 9, the first semiconductor layer 320 is disposed on a side of the first transparent conductive layer 310 away from the substrate 20. The first semiconductor layer 320 includes a channel C.

It will be noted that, a material of the first semiconductor layer 320 includes amorphous silicon, monocrystalline silicon, polycrystalline silicon, or a metal oxide semiconductor material. For example, the material of the first semiconductor layer 320 includes indium gallium zinc oxide and/or zinc oxide.

As shown in FIG. 9, the first conductive layer 330 is disposed on a side of the first semiconductor layer 320 away from the substrate 20. The first conductive layer 330 includes a first gate line 331 and a first transition line 332. The first gate line 331 overlaps with the channel C to form a driving transistor T. The first transition line 332 is connected to a portion of the first electrode 11 located outside the first recess 21, so as to transmit a voltage signal to the first electrode 11.

It will be noted that, a material of the first conductive layer 330 includes metal. For example, the material of the first conductive layer 330 includes at least one of aluminum, copper, or molybdenum.

As shown in FIG. 9, the second conductive layer 340 is disposed on a side of the first conductive layer 330 away from the substrate 20. The second conductive layer 340 includes a source S, a drain D, a second electrode 12 and a first connection line. The source S and the drain D are both connected to the channel C, and one of the source S and the drain D may be connected to the second electrode 12 through the first connection line.

It will be noted that, a material of the second conductive layer 340 includes metal. For example, the material of the second conductive layer 340 includes at least one of aluminum, copper, or molybdenum.

Based on the above, a surface of the light-emitting device 10 proximate to the substrate 20 may be connected to the portion of the first electrode 11 located in the first recess 21, and a surface of the light-emitting device 10 away from the substrate 20 may be connected to the second electrode 12, so that the light-emitting device 10 is driven by the first electrode 11 and the second electrode 12 to emit light. Furthermore, the second electrode 12, the source S, and the drain D are made of a same material and are disposed in the same layer, so that the second electrode 12, the source S, and the drain D may be fabricated in a same process, and the process is simple. Alternatively, the light-emitting device 10 and the driving transistor T may be directly fabricated on the substrate 20, so as to avoid increase in cost and yield loss caused by the die bonding process.

In addition, referring to FIG. 9, the light-emitting substrate 300 may further include a first buffer layer BF1, a first gate insulating layer GI1, a first interlayer insulating layer ILD1 and a second encapsulation layer 92. The first buffer layer BF1 is located between the first transparent conductive layer 310 and the first semiconductor layer 320. The first gate insulating layer GI1 is located between the first semiconductor layer 320 and the first conductive layer 330. The first interlayer insulating layer ILD1 is disposed between the first conductive layer 330 and the second conductive layer 340. The second encapsulation layer 92 is disposed on a side of the second conductive layer 340 away from the substrate 20 to play a role of insulation and protection, so as to reduce the risk of failure of circuits and the light-emitting devices 10 due to water and oxygen corrosion. The first transition line 332 penetrates the first buffer layer BF1 and the first gate insulating layer GI1 to be connected to the portion of the first electrode 11 located outside the first recess 21. The second electrode 12 penetrates the first buffer layer BF1, the first gate insulating layer GI1 and the first interlayer insulating layer ILD1 to be connected to the light-emitting device 10.

It will be noted that, a material of the first buffer layer BF1 includes silicon oxide and/or transparent resin. A material of the first gate insulating layer GI1 includes any of inorganic insulating materials of silicon nitride, silicon oxynitride and silicon oxide. A material of the first interlayer insulating layer ILD1 includes any of inorganic insulating materials of silicon nitride, silicon oxynitride and silicon oxide. The second encapsulation layer 92 may include, for example, at least one inorganic layer and at least one organic layer.

For example, referring to FIG. 10, the light-emitting substrate 300 includes a second transparent conductive layer 350, a second semiconductor layer 360, a third conductive layer 370 and a fourth conductive layer 380.

As shown in FIG. 10, the second transparent conductive layer 350 is disposed on the first surface 20A of the substrate 20 and is located on a side of the light-emitting device 10 proximate to the substrate 20. The second transparent conductive layer 350 includes a first electrode 11 and a second electrode 12. The first electrode 11 and the second electrode 12 are located in the first recess 21 and both extend outside the first recess 21, so as to facilitate the connection to the respective corresponding voltage signal lines.

It will be noted that, a material of the second transparent conductive layer 350 includes indium zinc oxide and/or indium tin oxide, so as to reduce the shielding of the light emitted by the light-emitting device 10 by the first electrode 11 and the second electrode 12 and improve the light extraction efficiency of the light-emitting substrate 300.

As shown in FIG. 10, the second semiconductor layer 360 is disposed on a side of the second transparent conductive layer 350 away from the substrate 20. The second semiconductor layer 360 includes a channel C.

It will be noted that, a material of the second semiconductor layer 360 includes amorphous silicon, monocrystalline silicon, polycrystalline silicon, or a metal oxide semiconductor material. For example, the material of the second semiconductor layer 360 includes indium gallium zinc oxide and/or zinc oxide.

As shown in FIG. 10, the third conductive layer 370 is disposed on a side of the second semiconductor layer 360 away from the substrate 20. The third conductive layer 370 includes a second gate line 371 and a second transition line 372. The second gate line 371 overlaps with the channel C to form a driving transistor T. The second transition line 372 is connected to a portion of the first electrode 11 located outside the first recess 21, so as to transmit a voltage signal to the first electrode 11.

It will be noted that, a material of the third conductive layer 370 includes metal. For example, the material of the third conductive layer 370 includes at least one of aluminum, copper, or molybdenum.

As shown in FIG. 10, the fourth conductive layer 380 is disposed on a side of the third conductive layer 370 away from the substrate 20. The fourth conductive layer 380 includes a source S, a drain D, and a third transition line 381. The source S and the drain D are both connected to the channel C, and one of the source S and the drain D may be connected to a portion of the second electrode 12 located outside the first recess 21 through the third transition line 381.

It will be noted that the material of the fourth conductive layer 380 includes metal. For example, the material of the fourth conductive layer 380 includes at least one of aluminum, copper, or molybdenum.

Based on the above, a surface of the light-emitting device 10 proximate to the substrate 20 may be connected to the portions of the first electrode 11 and the second electrode 12 that are located in the first recess 21, so that the light-emitting device 10 is driven by the first electrode 11 and the second electrode 12 to emit light. Furthermore, the light-emitting device 10 and the driving transistor T may be directly fabricated on the substrate 20 and connected to each other through the third transition line 381, so as to avoid increase in cost and yield loss caused by the die bonding process.

In addition, referring to FIG. 10, the light-emitting substrate 300 may further include a second buffer layer BF2, a second gate insulating layer GI2, a second interlayer insulating layer ILD2, and a third encapsulation layer 93. The second buffer layer BF2 is located between the second transparent conductive layer 350 and the second semiconductor layer 360 and fills the first recess 21. The second gate insulating layer GI2 is located between the second semiconductor layer 360 and the third conductive layer 370. The second interlayer insulating layer ILD2 is disposed between the third conductive layer 370 and the fourth conductive layer 380. The third encapsulation layer 93 is disposed on a side of the fourth conductive layer 380 away from the substrate 20 to play a role of insulation and protection, so as to reduce the risk of failure of circuits and the light-emitting devices 10 due to water and oxygen corrosion. The second transition line 372 penetrates the second buffer layer BF2 and the second gate insulating layer GI2 to be connected to the portion of the first electrode 11 located outside the first recess 21. The third transition line 381 penetrates the second buffer layer BF2, the second gate insulating layer GI2 and the second interlayer insulating layer ILD2 to be connected to the portion of the second electrode 12 located outside the first recess 21.

It will be noted that, a material of the second buffer layer BF2 includes silicon oxide and/or transparent resin. A material of the second gate insulating layer GI2 includes any of inorganic insulating materials of silicon nitride, silicon oxynitride and silicon oxide. A material of the second interlayer insulating layer ILD2 includes any of inorganic insulating materials of silicon nitride, silicon oxynitride and silicon oxide. The third encapsulation layer 93 may include, for example, at least one inorganic layer and at least one organic layer.

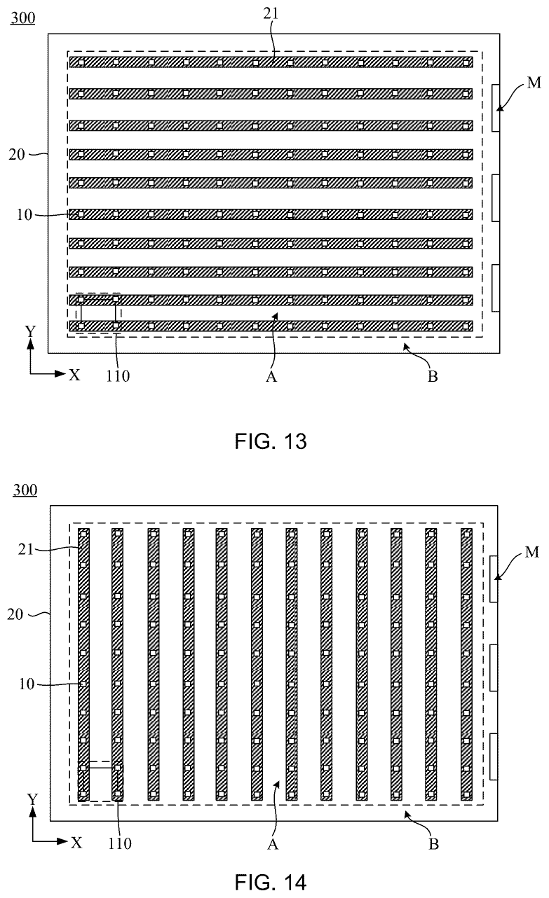

In some embodiments, referring to FIGS. 13 to 16, orthographic projection of light exit regions E of at least two light-emitting devices 10 on the second surface 20B of the substrate 20 are located within an orthographic projection of a same first recess 21 on the second surface 20B of the substrate 20 (referring to FIG. 12), so as to reduce the number of the first recesses 21 and reduce the process difficulty.

For example, referring to FIGS. 13, 14 and 15, the plurality of light-emitting devices 10 are arranged in an array, and orthographic projections of light exit regions E of at least two light-emitting devices 10 in a same row or a same column on the second surface 20B of the substrate 20 are located within an orthographic projection of a same first recess 21 on the second surface 20B of the substrate 20, so as to reduce the process difficulty.

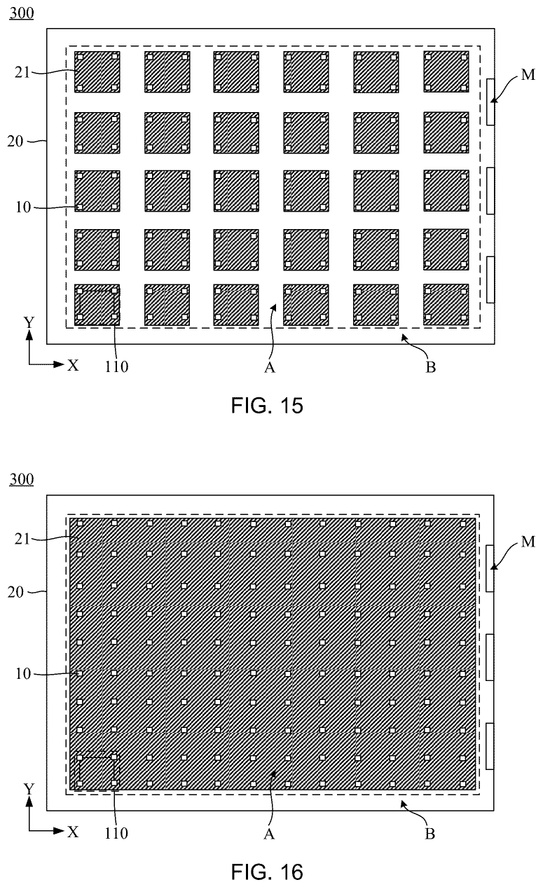

In some embodiments, as shown in FIG. 15, the light-emitting substrate 300 includes a plurality of light-emitting units 110, and a light-emitting unit 110 includes multiple light-emitting devices 10 connected in series and/or in parallel.

Based on this, orthographic projections of light exit regions E (referring to FIG. 7) of the multiple light-emitting devices 10 belonging to a same light-emitting unit 110 on the second surface 20B of the substrate 20 are located within an orthographic projection of a same first recess 21 on the second surface 20B of the substrate 20. In this way, the first recess 21 is formed according to the division of the light-emitting unit 110, which may simplify the forming process of the first recess 21, facilitate circuit wiring design, and help improve the brightness uniformity of the light-emitting substrate 300.

For example, as shown in FIG. 15, the plurality of light-emitting devices 10 are arranged in an array, and a light-emitting unit 110 includes four light-emitting devices 10 connected in series, and the four light-emitting devices 10 are adjacently arranged in two rows and two columns. The four light-emitting devices 10 are located in a same first recess 21 to reduce the process difficulty.

In some examples, as shown in FIG. 16, orthographic projections of light exit regions E of all the light-emitting devices on the second surface 20B of the substrate 20 are located within an orthographic projection of a same first recess 21 on the second surface 20B of the substrate 20.

For example, as shown in FIG. 16, the first recess 21 covers the entire light-emitting region A, and all the light-emitting devices 10 are disposed in the first recess 21.

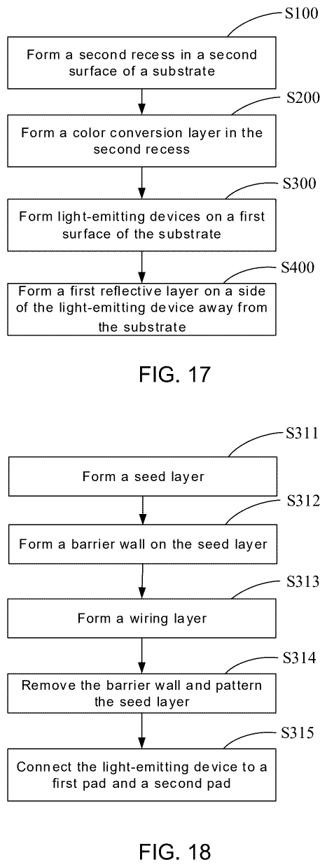

Some embodiments of the present disclosure provide a manufacturing method of a light-emitting substrate 300, which is used to manufacture the light-emitting substrate 300 as described in any one of the above embodiments. As shown in FIG. 17, the manufacturing method includes S100 to S400.

In S100, a second recess 22 is formed in a second surface 20B of a substrate 20.

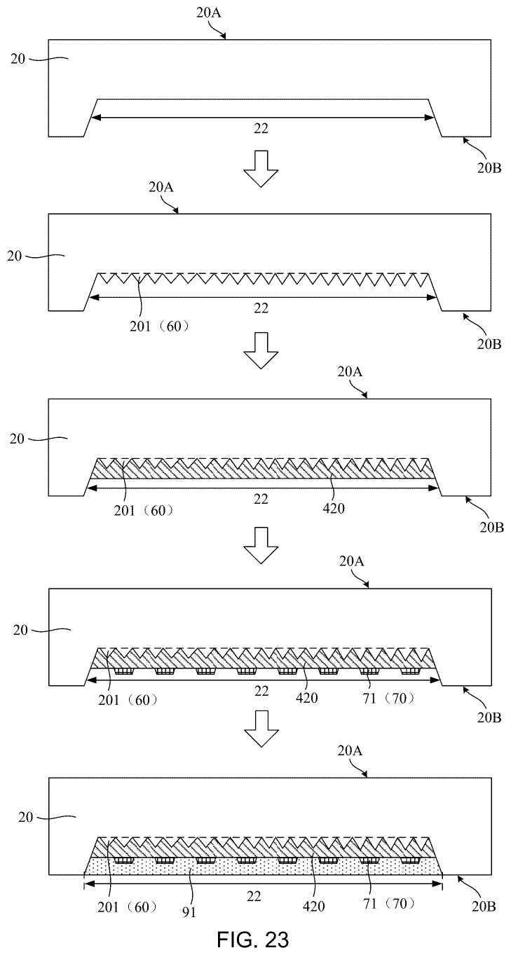

In the above step, as shown in FIG. 23, the second recess 22 may be formed by using a mask to etch the substrate 20. For example, a mask is separately disposed on the second surface 20B of the substrate 20, and the substrate 20 is etched by using the mask to form the second recess 22, and then the mask is removed. A material of the mask may include molybdenum, for example.

It will be noted that, etching may be performed by using a wet etching process. In this case, due to the isotropic characteristic of the wet etching process, a maximum radial length of the opening of the mask is substantially equal to a maximum depth of the second recess 22.

In S200, a color conversion layer 420 is formed in the second recess 22.

In the above step, as shown in FIG. 23, the color conversion layer 420 may be formed in the second recess 22 by using an inkjet printing process. For example, a fluorescent material or quantum dot material may be printed in the second recess 22 by using an inkjet printing process.

In S300, light-emitting devices 10 are formed on a first surface 20A of the substrate.

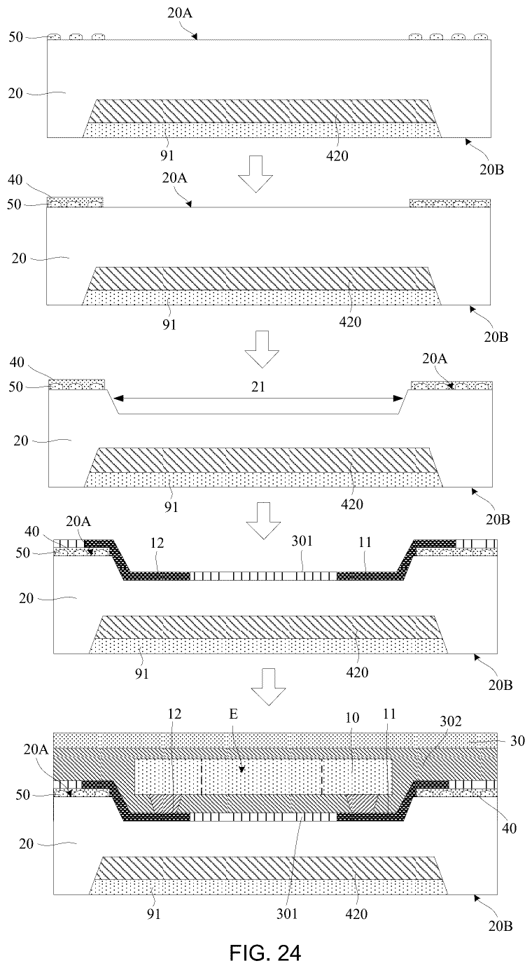

In the above step, as shown in FIG. 24, the first surface 20A and the second surface 20B are two opposite surfaces of the substrate 20. The light-emitting device 10 includes a light exit region E, and an orthographic projection of the light exit region E of the light-emitting device 10 on the substrate 20 is located within an orthographic projection of the color conversion layer 420 on the substrate 20.

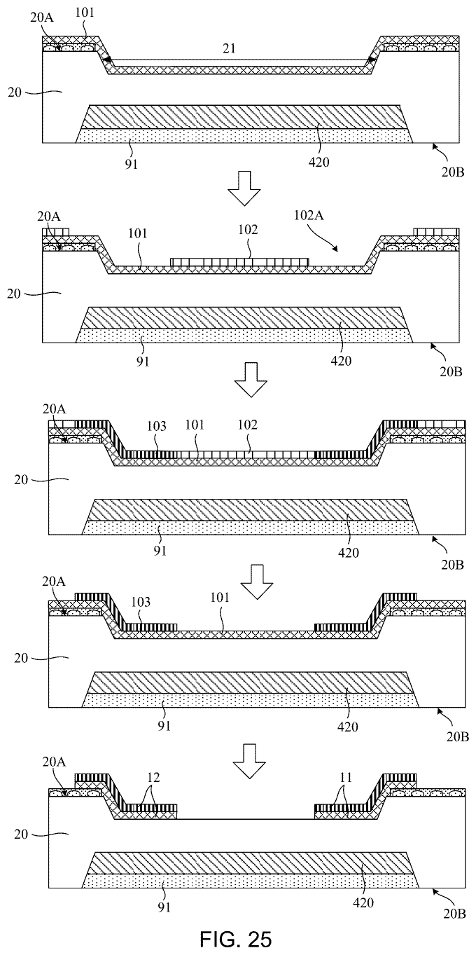

In some embodiments, referring to FIGS. 18 and 25, S300 includes S311 to S315.

In S311, a seed layer 101 is formed.

In the above step, as shown in FIG. 25, a whole layer of the seed layer 101 may be formed on the first surface 20A of the substrate 20 by using a sputtering process. A material of the seed layer 101 includes metal, such as molybdenum or copper.

In S312, a barrier wall 102 is formed on the seed layer 101.

In the above step, as shown in FIG. 25, the barrier wall 102 has a wiring gap 102A. The barrier wall 102 may be formed by sequentially using coating, exposure and development processes.

In S313, a wiring layer 103 is formed.

In the above step, as shown in FIG. 25, the wiring layer 103 is disposed in the wiring gap 102A and includes a first pad 11 and a second pad 12. The wiring layer 103 may be formed by using an electroplating process. A material of the wiring layer 103 includes metal, such as copper.

In S314, the barrier wall 102 is removed and the seed layer 101 is patterned.

In the above step, as shown in FIG. 25, the seed layer 101 is patterned such that an orthographic projection of the seed layer 101 on the substrate 20 substantially coincides with an orthographic projection of the wiring layer 103 on the substrate 20. The barrier wall 102 may be removed by using a stripping solution. The seed layer 101 may be patterned by using an etching process.

In S315, the light-emitting device 10 is connected to the first pad 11 and the second pad 12.

In the above step, as shown in FIG. 24, a first pin 131 and a second pin 132 of the light-emitting device 10 may be respectively connected to the first pad 11 and the second pad 12 by using a die bonding process.

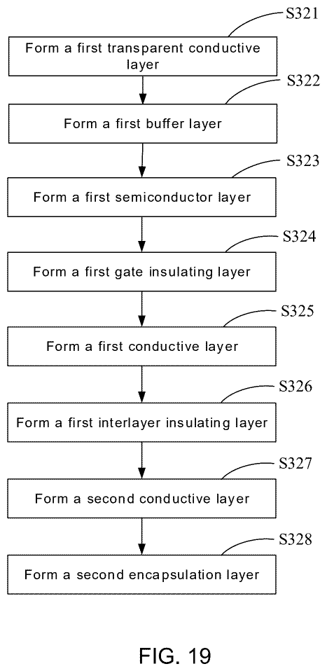

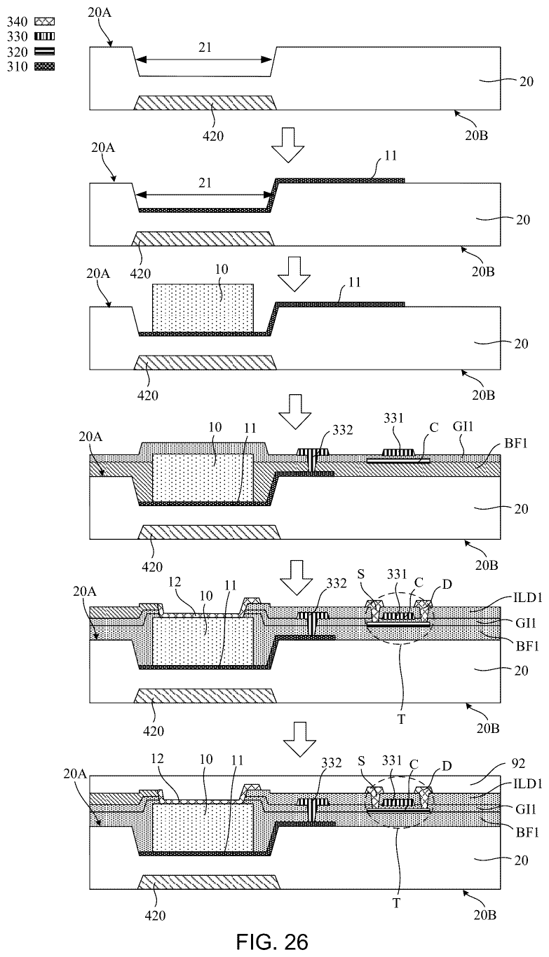

In some other embodiments, referring to FIGS. 19 and 26, S300 includes S321 to S328.

In S321, a first transparent conductive layer 310 is formed.

In the above step, as shown in FIG. 26, the first transparent conductive layer 310 is disposed on the first surface 20A of the substrate 20 and is located on a side of the light-emitting device 10 proximate to the substrate 20. The first transparent conductive layer 310 includes a first electrode 11. The first electrode 11 is located in the first recess 21 and extends outside the first recess 21 for convenience of being connected to a voltage signal line.

In S322, a first buffer layer BF1 is formed.

In the above step, as shown in FIG. 26, the first buffer layer BF1 is located on a side of the first transparent conductive layer 310 away from the substrate 20.

In S323, a first semiconductor layer 320 is formed.

In the above step, as shown in FIG. 26, the first semiconductor layer 320 is disposed on a side of the first buffer layer BF1 away from the substrate 20. The first semiconductor layer 320 includes a channel C.

In S324, a first gate insulating layer GI1 is formed.

In the above step, as shown in FIG. 26, the first gate insulating layer GI1 is located on a side of the first semiconductor layer 320 away from the substrate 20.

In S325, a first conductive layer 330 is formed.

In the above step, as shown in FIG. 26, the first conductive layer 330 is disposed on a side of the first semiconductor layer 320 away from the substrate 20. The first conductive layer 330 includes a first gate line 331 and a first transition line 332. The first gate line 331 overlaps with the channel C to form a driving transistor T. The first transition line 332 is connected to a portion of the first electrode 11 located outside the first recess 21, so as to transmit a voltage signal to the first electrode 11.

In S326, a first interlayer insulating layer ILD1 is formed.

In the above step, as shown in FIG. 26, the first interlayer insulating layer ILD1 is disposed on a side of the first conductive layer 330 away from the substrate 20.

In S327, a second conductive layer 340 is formed.

In the above step, as shown in FIG. 26, the second conductive layer 340 is disposed on a side of the first conductive layer 330 away from the substrate 20. The second conductive layer 340 includes a source S, a drain D, a second electrode 12 and a first connection line. The source S and the drain D are both connected to the channel C, and one of the source S and the drain D may be connected to the second electrode 12 through the first connection line.

In S328, a second encapsulation layer 92 is formed.

In the above step, as shown in FIG. 26, the second encapsulation layer 92 is disposed on a side of the second conductive layer 340 away from the substrate 20 to play a role of insulation and protection, so as to reduce the risk of failure of circuit and the light-emitting device 10 due to water and oxygen corrosion.

In S400, a first reflective layer 30 is formed on a side of the light-emitting device 10 away from the substrate 20.

In the above step, as shown in FIG. 24, the first reflective layer 30 covers at least the light-emitting device 10. The first reflective layer 30 may be formed by using a deposition process and/or a coating process.

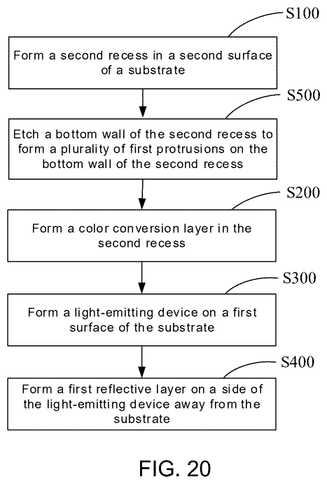

In some embodiments, referring to FIG. 20, between S100 and S200, the manufacturing method further includes S500.

In S500, a bottom wall of the second recess 22 is etched to form a plurality of first protrusions 201 on the bottom wall of the second recess 22.

In the above step, as shown in FIG. 23, the plurality of first protrusions 201 form a first light-homogenizing structure 60. The first protrusions 201 are substantially in a shape of at least one of a cone, a pyramid, and a spherical cap. In this case, the first protrusions 201 will disperse the incident light, and the light will be scattered in every direction, so that the brightness uniformity of the light-emitting substrate 300 is improved.

As shown in FIG. 23, the plurality of first protrusions 201 may be formed by using a mask to etch the bottom wall of the second recess 22 of the substrate 20. For example, a mask is separately disposed on the second surface 20B of the substrate 20, and the mask covers regions outside the second recess 22 and covers regions inside the second recess 22 where the first protrusions 201 need to be formed. In this case, the bottom wall of the second recess 22 is etched to form the plurality of first protrusions 201, and then the mask is removed.

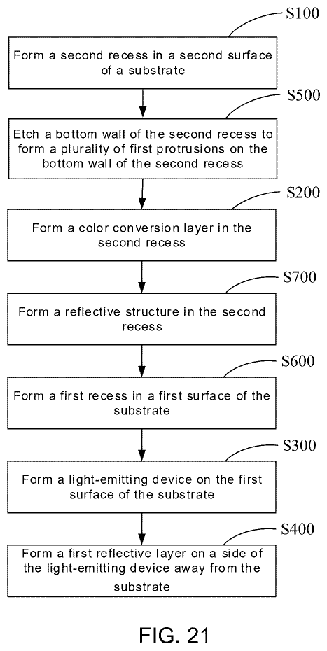

In some embodiments, referring to FIG. 21, before S300, the manufacturing method further includes S600.

In S600, a first recess 21 is formed in a first surface 20A of the substrate 20.

In the above step, as shown in FIG. 24, the first recess 21 may be formed by using a mask to etch the substrate 20. For example, a mask is separately disposed on the first surface 20A of the substrate 20, and the substrate 20 is etched by using the mask to form the first recess 21, and then the mask is removed. A material of the mask may include molybdenum, for example. In the process of S300, at least a portion of the light-emitting device 10 is located in the first recess 21.

It will be noted that, the etching may be performed by a wet etching process. In this case, due to the isotropic characteristic of the wet etching process, a maximum radial length of the opening of the mask is substantially equal to a maximum depth of the first recess 21.

In some embodiments, referring to FIG. 21, the manufacturing method further includes S700.

In S700, a reflective structure 70 is formed in the second recess 22.

In the above step, as shown in FIG. 23, the reflective structure 70 is disposed on a side of the color conversion layer 420 away from the substrate 20. The reflective structure 70 may include a plurality of reflective patterns 71, and the plurality of reflective patterns 71 are arranged at intervals. In this case, the plurality of reflective patterns 71 may be directly formed in the second recess 22 by using an evaporation process.

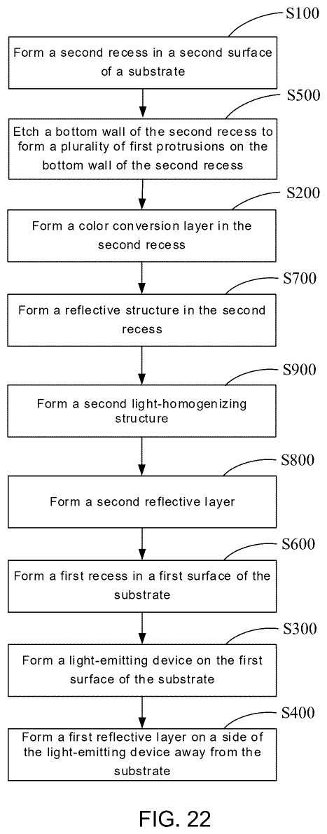

In some embodiments, referring to FIG. 22, before S600, the manufacturing method further includes S800.

In S800, a second reflective layer 40 is formed.

In the above step, as shown in FIG. 24, the second reflective layer 40 exposes at least a region where the light exit region E of the light-emitting device 10 is located. A reflective film may be firstly formed by using a sputtering or evaporation process, and then the second reflective layer 40 may be patterned and formed by using a photolithography process.

Based on this, referring to FIG. 22, before S800, the manufacturing method may further include S900.

In S900, a second light-homogenizing structure 50 is formed.

In the above step, as shown in FIG. 24, the second light-homogenizing structure 50 is disposed between the second reflective layer 40 and the substrate 20. The first surface 20A of the substrate 20 may be coated with a whole layer of resin material by using a coating process, then a plurality of second protrusions are formed by using exposure and development processes, and the plurality of second protrusions form the second light-homogenizing structure 50.

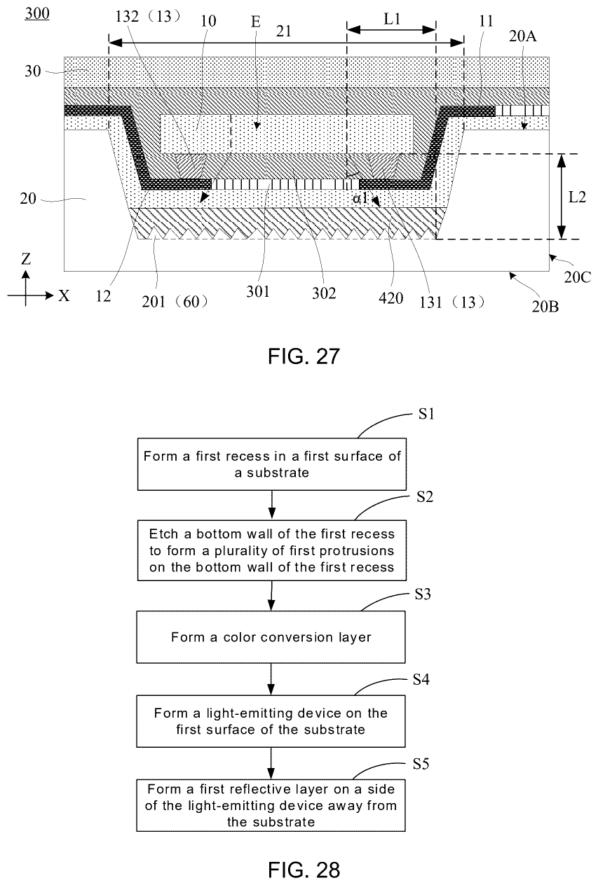

Some embodiments of the present disclosure provide a light-emitting substrate 300. Referring to FIG. 27, the light-emitting substrate 300 includes a light-emitting device 10, a substrate 20, a first reflective layer 30 and a color conversion layer 420.

As shown in FIG. 27, the substrate 20 has a first surface 20A and second surface 20B that are opposite to each other, and a side surface 20C connected to the first surface 20A and the second surface 20B.

As shown in FIG. 27, the light-emitting device 10 is disposed on the first surface 20A of the substrate 20. The light-emitting device 10 includes a light exit region E, and an orthographic projection of the light exit region E on the substrate 20 is located within an orthographic projection of the color conversion layer 420 on the substrate 20.

As shown in FIG. 27, the color conversion layer 420 is disposed on a side of the light-emitting device 10 toward the first surface 20A.

As shown in FIG. 27, the first reflective layer 30 is disposed on a side of the light-emitting device 10 away from the substrate 20, and covers at least the light-emitting device 10. In this way, the light emitted from the light-emitting device 10 and directed toward the first reflective layer 30 is reflected and then emitted from the second surface 20B of the substrate 20, thereby increasing the light extraction efficiency.

Based on this, the first surface 20A of the substrate 20 is provided with a first recess 21 therein, and a bottom wall of the first recess 21 of the substrate 20 is provided with a plurality of first protrusions 201 thereon. The plurality of first protrusions 201 form a first light-homogenizing structure 60. The first protrusions 201 are substantially in a shape of at least one of a cone, a pyramid, and a spherical cap. In this case, the first protrusions 201 will disperse the incident light, and the light will be scattered in every direction, so that the brightness uniformity of the light-emitting substrate 300 is improved.

In addition, the first light-homogenizing structure 60 is a portion of the substrate 20, so that there is no need to additionally provide other film layers that play a light-homogenizing role in the first recess 21, which not only saves materials but also reduces a depth of the first recess 21, so that the thickness of the substrate 20 may be reduced. As a result, the thickness of the display apparatus 1000 is reduced, so that the display apparatus 1000 is thinner and lighter.

In some embodiments, referring to FIG. 27, the color conversion layer 420 is located in the first recess 21, and the color conversion layer 420 located in the first recess 21 and the substrate 20 together occupy part of the dimension of the display apparatus 1000 in the third direction Z; that is, a portion of the color conversion layer 420 located in the first recess 21 does not need to additionally occupy the dimension of the display apparatus 1000 in the third direction Z. Based on this, in comparison with the related art, the thickness of the display apparatus 1000 provided in the embodiments of the present disclosure may be reduced, so as to make the display apparatus 1000 thinner and lighter.

In some other embodiments, the color conversion layer 420 is located on the second surface 20B of the substrate 20 and covers the entire light-emitting region A. All the light emitted by the light-emitting device 10 may be converted by the color conversion layer 420 and emitted after being homogenized by the first light-homogenizing structure 60.

In some embodiments, referring to FIG. 27, at least a portion of the light-emitting device 10 is located in the first recess 21. For example, the entire light-emitting device 10 is located in a first recess 21. For another example, in the third direction Z of the display apparatus 1000, the thickness of the light-emitting device 10 is greater than the depth of the first recess 21, a portion of the light-emitting device 10 is located in the first recess 21, and another portion of the light-emitting device 10 exceeds the opening of the first recess 21 and is exposed outside the first recess 21.

In this case, the portion of the light-emitting device 10 located in the first recess 21 and the substrate 20 together occupy part of the dimension of the display apparatus 1000 in the third direction Z, i.e., the portion of the light-emitting device 10 located in the first recess 21 does not need to additionally occupy the dimension of the display apparatus 1000 in the third direction Z, which may further reduce the thickness of the display apparatus 1000, making the display apparatus 1000 thinner and lighter.

In some embodiments, referring to FIG. 27, a distance between a border of an orthographic projection of a bottom wall of the first recess 21 on the second surface 20B of the substrate 20 and a border of an orthographic projection of a light exit region E of the light-emitting device 10 on the second surface 20B of the substrate 20 is a first distance L1, and a distance between the light-emitting device 10 and the bottom wall of the first recess 21 is a second distance L2.

The first distance L1 is greater than or equal to a product of the second distance L2 and a tangent value of the light exit angle α1 of the light exit region E of the light-emitting device 10, so that all the light emitted by the light-emitting device 10 may be directed toward the bottom wall of the first recess 21, and may be emitted after being homogenized by the first light-homogenizing structure 60.

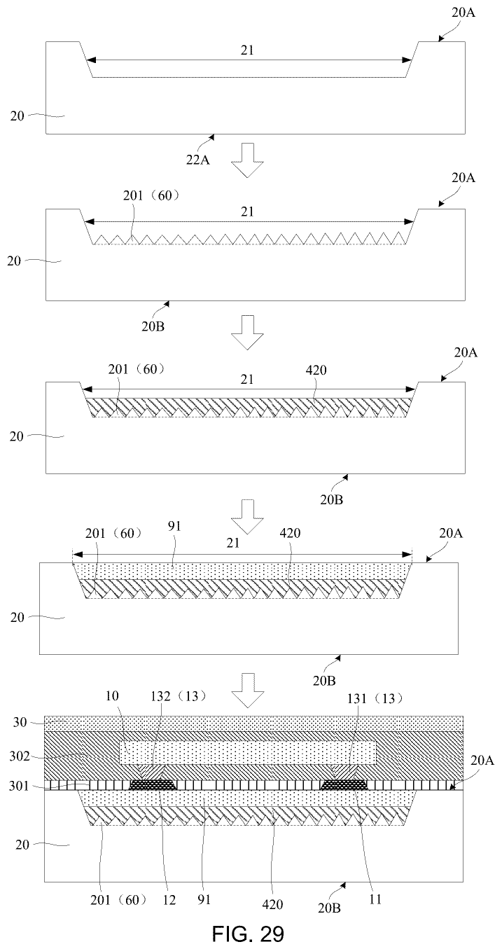

Some embodiments of the present disclosure provide a manufacturing method of a light-emitting substrate 300, which is used to manufacture the light-emitting substrate 300 in the above embodiments. Referring to FIGS. 28 and 29, the manufacturing method includes S1 to S5.

In S1, a first recess 21 is formed in a first surface 20A of a substrate 20.

In the above step, as shown in FIG. 29, the first recess 21 may be formed by using a mask to etch the substrate 20. For example, a mask is separately disposed on the first surface 20A of the substrate 20, and the substrate 20 is etched by using the mask to form the first recess 21, and then the mask is removed. A material of the mask may include molybdenum, for example.

It will be noted that, the etching may be performed by using a wet etching process. In this case, due to the isotropic characteristic of the wet etching process, a maximum radial length of the opening of the mask is substantially equal to a maximum depth of the first recess 21.

In S2, a bottom wall of the first recess 21 is etched to form a plurality of first protrusions 201 on the bottom wall of the first recess 21.

In the above step, as shown in FIG. 29, the plurality of first protrusions 201 form a first light-homogenizing structure 60. The first protrusions 201 are substantially in a shape of at least one of a cone, a pyramid, and a spherical cap. In this case, the first protrusions 201 will disperse the incident light, and the light will be scattered in every direction, so that the brightness uniformity of the light-emitting substrate 300 is improved.

As shown in FIG. 29, the plurality of first protrusions 201 may be formed by using a mask to etch the bottom wall of the first recess 21 of the substrate 20. For example, a mask is separately disposed on the first surface 20A of the substrate 20, and the mask covers regions outside the first recess 21 and covers regions inside the first recess 21 where the first protrusions 201 need to be formed. In this case, the bottom wall of the first recess 21 is etched to form a plurality of first protrusions 201, and then the mask is removed.

In S3, a color conversion layer 420 is formed.

In the above step, as shown in FIG. 29, the color conversion layer 420 is disposed on the second surface 20B of the substrate 20 or in the first recess 21 of the substrate 20. The first surface 20A and the second surface 20B are two opposite surfaces of the substrate 20.

In a case where the color conversion layer 420 is disposed in the first recess 21 of the substrate 20, the color conversion layer 420 may be formed in the first recess 21 by using an inkjet printing process. For example, a fluorescent material or quantum dot material may be printed in the first recess 21 by using an inkjet printing process.

In S4, a light-emitting device 10 is formed on the first surface 20A of the substrate 20.

In the above step, as shown in FIGS. 27 and 29, the light-emitting device 10 includes a light exit region E, and an orthographic projection of the light exit region E of the light-emitting device 10 on the substrate 20 is located within an orthographic projection of the color conversion layer 420 on the substrate 20.

It will be noted that, for the steps of forming the light-emitting device 10, reference may be made to the aforementioned description, and details will not be repeated here in the embodiments of the present disclosure.

In S5, a first reflective layer 30 is formed on a side of the light-emitting device 10 away from the substrate 20.

In the above step, as shown in FIG. 29, the first reflective layer 30 covers at least the light-emitting device 10. The first reflective layer 30 may be formed by using a deposition process and/or a coating process.

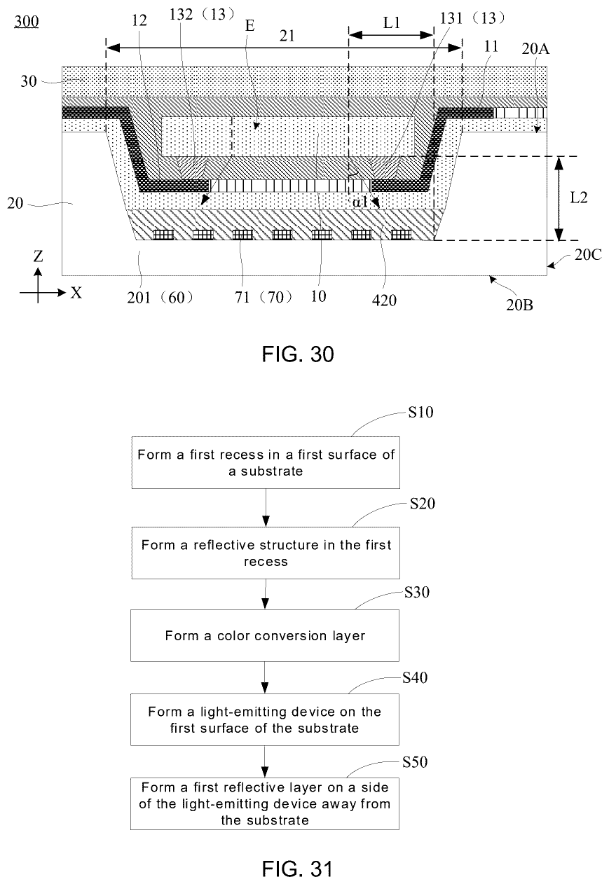

Some embodiments of the present disclosure provide a light-emitting substrate 300. Referring to FIG. 30, the light-emitting substrate 300 includes a light-emitting device 10, a substrate 20, a first reflective layer 30, a color conversion layer 420 and a reflective structure 70.

As shown in FIG. 30, the substrate 20 has a first surface 20A and second surface 20B that are opposite to each other, and a side surface 20C connected to the first surface 20A and the second surface 20B. The first surface 20A of the substrate 20 is provided with a first recess 21 therein.

As shown in FIG. 30, the light-emitting device 10 is disposed on the first surface 20A of the substrate 20. The light-emitting device 10 includes a light exit region E, and an orthographic projection of the light exit region E on the substrate 20 is within an orthographic projection of the color conversion layer 420 on the substrate 20.

As shown in FIG. 30, the color conversion layer 420 is disposed on a side of the light-emitting device 10 towards the first surface 20A.

As shown in FIG. 30, the first reflective layer 30 is disposed on a side of the light-emitting device 10 away from the substrate 20 and covers at least the light-emitting device 10. In this way, the light emitted from the light-emitting device 10 and directed toward the first reflective layer 30 is reflected and emitted from the second surface 20B of the substrate 20, thereby increasing the light extraction efficiency.

As shown in FIG. 30, the reflective structure 70 is disposed in the first recess 21 of the substrate 20, and the reflective structure 70 is configured to reflect the received light. For details of the reflective structure 70, reference may be made to the aforementioned description, and the details will not be repeated here in the embodiments of the present disclosure.

In this case, for the light emitted by the light-emitting device 10 and directed toward a region where the first recess 21 is located, a part of light may be reflected by the reflective structure 70 into the substrate 20 and emitted from other regions. Thus, the light output from the region where the first recess 21 is located is reduced, and the light output from regions between first recesses 21 is increased, so that the brightness uniformity of the light-emitting substrate 300 is improved.

Moreover, the reflective structure 70 does not need to occupy additional dimension of the display apparatus 1000 in the third direction Z, which is beneficial for thinness and lightness of the display apparatus 1000. That is, the brightness uniformity of the light-emitting substrate 300 may be improved without increasing the thickness of the display apparatus 1000.

In some embodiments, referring to FIG. 30, the color conversion layer 420 is also located in the first recess 21, and the reflective structure 70 is located at a side of the color conversion layer 420 proximate to the substrate 20, so as to prevent the light emitted by the light-emitting device 10 from being directly emitted without being converted by the color conversion layer 420, thereby reducing the risk of color deviation.

The color conversion layer 420 located in the first recess 21 and the substrate 20 together occupy part of the dimension of the display apparatus 1000 in the third direction Z; that is, the color conversion layer 420 located in the first recess 21 does not need to occupy additional dimension of the display apparatus 1000 in the third direction Z. Based on this, in comparison with the related art, the thickness of the display apparatus 1000 provided in the embodiments of the present disclosure is reduced, so that the display apparatus 1000 is thinner and lighter.

In some other embodiments, the color conversion layer 420 is located on the second surface 20B of the substrate 20 and covers the entire light-emitting region A. Thus, all the light emitted by the light-emitting device 10 may be converted by the color conversion layer 420 and emitted after being reflected by the reflective structure 70.

In some embodiments, referring to FIG. 30, at least a portion of the light-emitting device 10 is located in the first recess 21. For example, the entire light-emitting device 10 is located in a first recess 21. For another example, in the third direction Z of the display apparatus 1000, the thickness of the light-emitting device 10 is greater than the depth of the first recess 21, a portion of the light-emitting device 10 is located in the first recess 21, and another portion of the light-emitting device 10 exceeds the opening of the first recess 21 and is exposed outside the first recess 21.

In this case, the portion of the light-emitting device 10 located in the first recess 21 and the substrate 20 together occupy part of the dimension of the display apparatus 1000 in the third direction Z; that is, the portion of the light-emitting device 10 located in the first recess 21 does not need to additionally occupy the dimension of the display apparatus 1000 in the third direction Z. In this way, the thickness of the display apparatus 1000 may be further reduced, and the display apparatus 1000 may be thinner and lighter.

In some embodiments, referring to FIG. 30, a distance between a border of an orthographic projection of a bottom wall of the first recess 21 on the second surface 20B of the substrate 20 and a border of an orthographic projection of the light exit region E of the light-emitting device 10 on the second surface 20B of the substrate 20 is a first distance L1, and a distance between the light-emitting device 10 and the bottom wall of the first recess 21 is a second distance L2.

The first distance L1 is greater than or equal to a product of the second distance L2 and a tangent value of the light exit angle α1 of the light exit region E of the light-emitting device 10. Thus, all the light emitted by the light-emitting device 10 may be directed toward the bottom wall of the first recess 21, and after passing through the reflective structure 70, a part of the light is directly emitted, and another part of the light is reflected into the substrate 20 and emitted from other regions, so that the brightness uniformity of the light-emitting substrate 300 is improved.

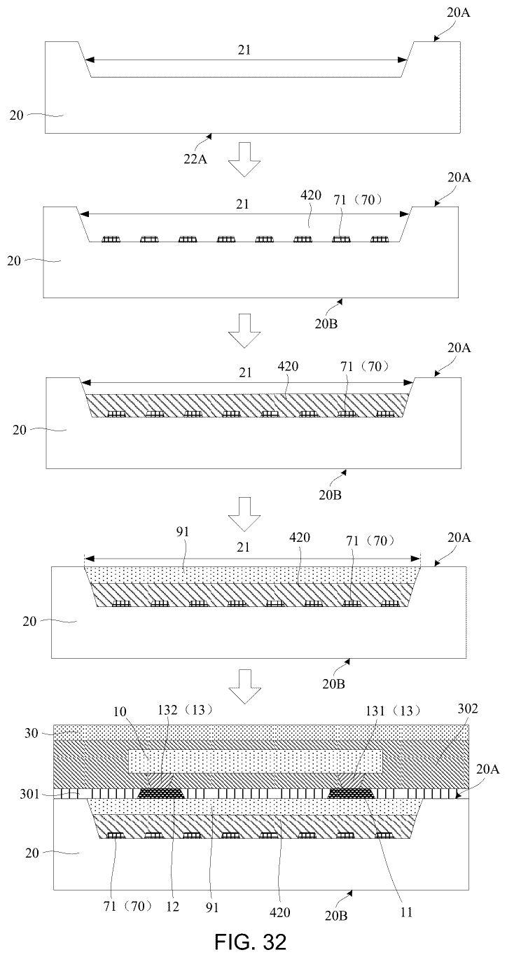

Some embodiments of the present disclosure provide a manufacturing method of a light-emitting substrate 300, which is used to manufacture the light-emitting substrate 300 in the above embodiment. As shown in FIGS. 31 and 32, the manufacturing method includes S10 to S50.

In S10, a first recess 21 is formed in a first surface 20A of a substrate 20.

In the above step, as shown in FIG. 32, the first recess 21 may be formed by using a mask to etch the substrate 20. For example, a mask is separately disposed on the first surface 20A of the substrate 20, and the substrate 20 is etched by using the mask to form the first recess 21, and then the mask is removed. A material of the mask may include molybdenum, for example.

It will be noted that, the etching may be performed by a wet etching process. In this case, due to the isotropic characteristic of the wet etching process, a maximum radial length of the opening of the mask is substantially equal to a maximum depth of the first recess 21.

In S20, a reflective structure 70 is formed in the first recess 21.

In the above step, as shown in FIG. 32, the reflective structure 70 is disposed on a side of a color conversion layer 420 proximate to the substrate 20. The reflective structure 70 may include a plurality of reflective patterns 71, and the plurality of reflective patterns 71 are arranged at intervals. In this case, the plurality of reflective patterns 71 may be directly formed in the first recess 21 by using an evaporation process.

In S30, a color conversion layer 420 is formed.

In the above step, as shown in FIG. 32, the color conversion layer 420 is disposed on the second surface 20B of the substrate 20 or in the first recess 21, and the color conversion layer 420 is located on a side of the reflective structure 70 away from the substrate 20. The first surface 21A and the second surface 20B are two opposite surfaces of the substrate 20.

In a case where the color conversion layer 420 is disposed in the first recess 21 of the substrate 20, the color conversion layer 420 may be formed in the first recess 21 by using an inkjet printing process. For example, a fluorescent material or quantum dot material may be printed in the first recess 21 by using an inkjet printing process.

In S40, a light-emitting device 10 is formed on the first surface 20A of the substrate 20.

In the above step, as shown in FIGS. 30 and 32, the light-emitting device 10 includes a light exit region E, and an orthographic projection of the light exit region E of the light-emitting device 10 on the substrate 20 is located within an orthographic projection of the color conversion layer 420 on the substrate 20.

It will be noted that, for the steps of forming the light-emitting device 10, reference may be made to the aforementioned description, and details will not be repeated here in the embodiments of the present disclosure.

In S50, a first reflective layer 30 is formed on a side of the light-emitting device 10 away from the substrate 20.

In the above step, as shown in FIG. 32, the first reflective layer 30 covers at least the light-emitting device 10. The first reflective layer 30 may be formed by using a deposition process and/or a coating process.

In the description of the present specification, specific features, structures, materials or characteristics may be combined in any one or more embodiments or examples in a suitable manner.

The above are only specific embodiments of the present disclosure, but the protection scope of the present disclosure is not limited thereto, and variations or substitutions that any person skilled in the art may conceive of within the technical scope disclosed by the present disclosure, should fall within the protection scope of the present disclosure. Therefore, the protection scope of the present disclosure should be subjected to the protection scope of the claims.

1. A light-emitting substrate, comprising:
a substrate having a first surface and a second surface that are opposite to each other, wherein the second surface of the substrate is provided with a second recess therein;
light-emitting devices disposed on the first surface of the substrate, wherein a light-emitting device of the light-emitting devices includes a light exit region;
a color conversion layer disposed on a side of the light-emitting device toward the second surface, wherein the color conversion layer is located in the second recess, and an orthographic projection of the light exit region of the light-emitting device on the substrate is located within an orthographic projection of the color conversion layer on the substrate; and
a first reflective layer disposed on a side of the light-emitting devices away from the substrate and covering at least the light-emitting devices.

2. The light-emitting substrate according to claim 1, further comprising:
a first light-homogenizing structure disposed in the second recess of the substrate, wherein the first light-homogenizing structure is configured to scatter received light.

3. The light-emitting substrate according to claim 2, wherein the first light-homogenizing structure includes a plurality of first protrusions, and the plurality of first protrusions are disposed on a bottom wall of the second recess of the substrate; and/or
the first light-homogenizing structure includes a scattering layer disposed on a side of the color conversion layer proximate to or away from the substrate.

4. (canceled)

5. (canceled)

6. The light-emitting substrate according to claim 1, further comprising:
a reflective structure disposed in the second recess of the substrate, and located on a side of the color conversion layer away from the substrate, wherein the reflective structure is configured to reflect received light: or
the light-emitting substrate further comprising the reflective structure disposed in the second recess of the substrate and located on a side of the color conversion layer away from the substrate, wherein the reflective structure is configured to reflect received light, the reflective structure includes a plurality of reflective patterns, and the plurality of reflective patterns are arranged at intervals.

7. (canceled)

8. (canceled)

9. The light-emitting substrate according to claim 1, wherein the first surface of the substrate is provided with first recesses therein, and at least a portion of the light-emitting device is located in a first recess.

10. The light-emitting substrate according to claim 9, further comprising:
a first transparent conductive layer disposed on the first surface of the substrate and located on a side of the light-emitting device proximate to the substrate, wherein the first transparent conductive layer includes a first electrode, the first electrode is located in the first recess and extends outside the first recess; a surface of the light-emitting device proximate to the substrate is connected to a portion of the first electrode located in the first recess;
a first semiconductor layer disposed on a side of the first transparent conductive layer away from the substrate, wherein the first semiconductor layer includes a channel;
a first conductive layer disposed on a side of the first semiconductor layer away from the substrate, wherein the first conductive layer includes a first gate line and a first transition line; the first gate line overlaps with the channel; the first transition line is connected to a portion of the first electrode located outside the first recess; and
a second conductive layer disposed on a side of the first conductive layer away from the substrate, wherein the second conductive layer includes a source, a drain, a second electrode and a first connection line; a surface of the light-emitting device away from the substrate is connected to the second electrode, and one of the source and the drain is connected to the second electrode through the first connection line; the source and the drain are both connected to the channel; or
the light-emitting substrate further comprising:
a second transparent conductive layer disposed on the first surface of the substrate and located on a side of the light-emitting device proximate to the substrate, wherein the second transparent conductive layer includes a first electrode and a second electrode, the first electrode and the second electrode are both located in the first recess and extend outside the first recess; a surface of the light-emitting device proximate to the substrate is connected to portions of the first electrode and the second electrode that are located in the first recess;
a second semiconductor layer disposed on a side of the second transparent conductive layer away from the substrate, wherein the second semiconductor layer includes a channel,
a third conductive layer disposed on a side of the second semiconductor layer away from the substrate, wherein the third conductive layer includes a second gate line and a second transition line; the second gate line overlaps with the channel; the second transition line is connected to a portion of the first electrode located outside the first recess; and
a fourth conductive layer disposed on a side of the third conductive layer away from the substrate, wherein the fourth conductive layer includes a source, a drain and a third transition line; one of the source and the drain is connected toa portion of the second electrode located outside the first recess through the third transition line; the source and the drain are both connected to the channel.

11. (canceled)

12. The light-emitting substrate according to claim 10, wherein orthographic projections of at least two light-emitting devices of the light-emitting devices on the second surface of the substrate are located within an orthographic projection of a same first recess on the second surface of the substrate.

13. The light-emitting substrate according to claim 12, wherein the light-emitting devices are arranged in an array, and orthographic projections of light exit regions of at least two light-emitting devices in a same row or a same column are located within an orthographic projection of a same first recess on the second surface of the substrate; and/or
the light-emitting substrate further comprises light-emitting units each including multiple light-emitting devices that are connected in series and/or in parallel, wherein orthographic projections of light exit regions of light-emitting devices that belongs to a same light-emitting unit on the second surface of the substrate are located within an orthographic projection of a same first recess on the second surface of the substrate; and/or
orthographic projections of light exit regions of all the light-emitting devices on the second surface of the substrate are located within an orthographic projection of a same first recess on the second surface of the substrate.

14. (canceled)

15. (canceled)

16. The light-emitting substrate according to claim 1, wherein
the substrate further includes a side surface connected to the first surface and the second surface, and the light-emitting substrate further comprises:
a light leakage preventing layer disposed on the side surface of the substrate; and/or
the light-emitting substrate further comprises: a second reflective layer disposed on the first surface of the substrate and exposing at least a region where the light exit region of the light-emitting device is located; and/or
the light-emitting substrate further comprises: a first encapsulation layer disposed on a side of the color conversion layer away from the substrate.

17. The light-emitting substrate according to claim 1, wherein the first surface of the substrate is provided with a first recess therein, a distance between a border of an orthographic projection of a bottom wall of the first recess on the second surface of the substrate and a border of an orthographic projection of the light exit region of the light-emitting device on the second surface of the substrate is a first distance, and a distance between the light-emitting device and the bottom wall of the first recess is a second distance;
the first distance is greater than or equal to a product of the second distance and a tangent value of a light exit angle of the light exit region of the light-emitting device; and/or
a distance between a border of an orthographic projection of a bottom wall of the second recess on the second surface of the substrate and a border of an orthographic projection of the light exit region of the light-emitting device on the second surface of the substrate is a third distance, and a distance between the light-emitting device and the bottom wall of the second recess is a fourth distance; the third distance is greater than or equal to a product of the fourth distance and a tangent value of a light exit angle of the light exit region of the light-emitting device.

18-20. (canceled)

21. A light-emitting substrate, comprising:
a substrate having a first surface and a second surface that are opposite to each other, wherein the first surface of the substrate is provided with a first recess therein, and a bottom wall of the first recess of the substrate is provided with a plurality of first protrusions thereon;
a light-emitting device disposed on the first surface of the substrate, wherein the light-emitting device includes a light exit region;
a color conversion layer disposed on a side of the light-emitting device toward the second surface, wherein an orthographic projection of the light exit region of the light-emitting device on the substrate is located within an orthographic projection of the color conversion layer on the substrate; and
a first reflective layer disposed on a side of the light-emitting device away from the substrate and covering at least the light-emitting device.

22. The light-emitting substrate according to claim 21, wherein the color conversion layer is located in the first recess; and/or at least a portion of the light-emitting device is located in the first recess.

23. A light-emitting substrate, comprising:
a substrate having a first surface and a second surface that are opposite to each other, wherein the first surface of the substrate is provided with a first recess therein;
a light-emitting device disposed on the first surface of the substrate, wherein the light-emitting device includes a light exit region;
a color conversion layer disposed on a side of the light-emitting device toward the second surface, wherein an orthographic projection of the light exit region of the light-emitting device on the substrate is located within an orthographic projection of the color conversion layer on the substrate;
a first reflective layer disposed on a side of the light-emitting device away from the substrate and covering at least the light-emitting device; and
a reflective structure disposed in the first recess of the substrate, wherein the reflective structure is configured to reflect received light.

24. The light-emitting substrate according to claim 23, wherein the color conversion layer is located in the first recess and located on a side of the reflective structure away from the substrate; and/or at least a portion of the light-emitting device is located in the first recess.

25. A backlight module, comprising:
the light-emitting substrate according to claim 1, wherein the light-emitting substrate has a light exit side and a non-light exit side that are opposite to each other;
a diffusion sheet disposed on the light exit side of the light-emitting substrate; and
a composite film disposed on a side of the diffusion sheet away from the light-emitting substrate.

26. A display apparatus, comprising:
the backlight module according to claim 25; and
a display panel disposed on a side of the composite film in the backlight module away from the light-emitting substrate.

27-32. (canceled)

33. A backlight module, comprising:
the light-emitting substrate according to claim 21, wherein the light-emitting substrate has a light exit side and a non-light exit side that are opposite to each other;
a diffusion sheet disposed on the light exit side of the light-emitting substrate; and
a composite film disposed on a side of the diffusion sheet away from the light-emitting substrate.

34. A backlight module, comprising:
the light-emitting substrate according to claim 23, wherein the light-emitting substrate has a light exit side and a non-light exit side that are opposite to each other;
a diffusion sheet disposed on the light exit side of the light-emitting substrate; and
a composite film disposed on a side of the diffusion sheet away from the light-emitting substrate.

35. A display apparatus, comprising:
the backlight module according to claim 33; and
a display panel disposed on a side of the composite film in the backlight module away from the light-emitting substrate.

36. A display apparatus, comprising:
the backlight module according to claim 34; and
a display panel disposed on a side of the composite film in the backlight module away from the light-emitting substrate.
